(19) United States
(12) Patent Application Publication
(10) Pub. No.: US 2026/0029875 A1
(43) Pub. Date: Jan. 29, 2026

(54) In-Cell Touch Display Panel

(71) Applicant: LG Display Co., Ltd., Seoul (KR)

(72) Inventors: Sung Hyun Jang, Paju-si (KR); Sang Soo Hwang, Paju-si (KR); Eun Min Jo, Paju-si (KR)

(21) Appl. No.: 19/229,840

(22) Filed: Jun. 5, 2025

(30) Foreign Application Priority Data
Jul. 26, 2024 (KR) 10-2024-0099484

(51) Int. Cl. G06F 3/041; G09G 3/32; H10H 29/49; H10H 29/80

(52) U.S. Cl. CPC G06F 3/0418; G06F 3/04164; G06F 3/04166; G09G 3/32; H10H 29/49; H10H 29/8321; G06F 3/0412; G06F 2203/04107; G09G 2300/0426; G09G 2310/0286; G09G 2310/08; G09G 2320/0233; G09G 2320/0242; G09G 2330/10; G09G 2354/00

(57) ABSTRACT

An in-cell touch display panel includes a first common electrode connected to first pixels in a display area, a second common electrode connected to second pixels in the display area, and a first pixel driver in the display area and configured to write pixel data to the first pixels and the second pixels and supply a voltage to the first common electrode and the second common electrode.

### CROSS-REFERENCE TO RELATED APPLICATION

This application claims priority to and the benefit of Republic of Korea Patent Application No. 10-2024-0099484 filed on Jul. 26, 2024, which is hereby incorporated by reference in its entirety for all purposes.

### 1. FIELD OF TECHNOLOGY

The present disclosure relates to a display panel, in particular, but not limited to, an in-cell touch display panel.

### 2. DISCUSSION OF RELATED ART

A display device is applied to various electronic devices such as televisions (TVs), mobile phones, video phones, smart watches, watch phones, wearable devices, foldable devices, portable multimedia players (PMP), personal digital assistants (PDA), laptops, and tablets.

Examples of display devices include an organic light emitting display (OLED) that emits light by itself, and a liquid crystal display (LCD) that requires a separate light source, a plasma display panel (PDP), an electroluminescent display device, an electrowetting display device, an electrophoresis display (EPD) device, a stretchable display device, flexible display device, etc.

Recently, a display device including inorganic light emitting elements (inorganic light emitting diodes; LEDs) has been attracting attention as a next-generation display device. Since an inorganic light emitting element is made of an inorganic material rather than an organic material, the light emitting diode can have a higher lighting speed and more excellent light emitting efficiency and display a video with high luminance compared to a liquid crystal display or an organic light emitting display.

### SUMMARY

The present disclosure is directed to providing an in-cell touch display panel with a reduced thickness of a display panel.

The present disclosure is directed to providing an in-cell touch display panel with increased accuracy of touch sensing and reduced time required for touch sensing.

The objects according to embodiments of the present disclosure are not limited to the objects that are mentioned above, and other objects that are not mentioned can be clearly understood by those skilled in the art from the description below.

According to an embodiment of the present disclosure, an in-cell touch display panel comprises: a first common electrode connected to first pixels in a display area; a second common electrode connected to second pixels in the display area; and a first pixel driver in the display area, the first pixel driver configured to write pixel data to the first pixels and the second pixels and supply a voltage to the first common electrode and the second common electrode.

According to an embodiment of the present disclosure, an in-cell touch display device comprises: a plurality of pixels in a display area that displays an image; a plurality of touch units that each include a plurality of touch groups, wherein each of the plurality of touch groups of each of the plurality of touch units comprises a first touch group including a first common electrode that is connected to first pixels of the touch unit from the plurality of pixels and a second touch group including a second common electrode that is connected to second pixels of the touch unit from the plurality of pixels but not the first pixels of the touch unit; and a pixel driver configured to output a touch driving signal to the first common electrode of the first touch group of each of the plurality of touch units to sense touch of the first touch group during a first touch period and output a common voltage to the second common electrode of the second touch group of each of the plurality of touch units during the first touch period such that the second pixels of each of the plurality of touch units display an image during the first touch period.

Specific details according to various examples of the present disclosure other than the aspect mentioned above are included in the description and drawings below.

### BRIEF DESCRIPTION OF THE DRAWINGS

The above and other objects, features and advantages of the present disclosure will become more apparent to those of ordinary skill in the art by describing exemplary embodiments thereof in detail with reference to the accompanying drawings, in which:

FIG. 1 is an exploded perspective view of a display device according to an embodiment of the present disclosure;

FIG. 2 is a plan view illustrating the display device according to an embodiment of the present disclosure;

FIG. 3 is an enlarged view illustrating the display device according to an embodiment of the present disclosure;

FIG. 4 is a diagram illustrating a circuit structure according to an embodiment of the present disclosure;

FIG. 5 is a diagram illustrating a plurality of touch blocks disposed on an in-cell touch display panel according to an embodiment of the present disclosure;

FIG. 6 is a diagram illustrating a driving method for an in-cell touch display panel according to an embodiment of the present disclosure;

FIGS. 7A to 7E are diagrams illustrating a driving method for an in-cell touch display panel according to an embodiment of the present disclosure;

FIG. 8 is an enlarged view of a touch group according to an embodiment of the present disclosure;

FIG. 9 is an enlarged view of pixels disposed in the touch group according to an embodiment of the present disclosure;

FIG. 10 is an enlarged view of a touch group according to another embodiment of the present disclosure;

FIG. 11 is a cross-sectional view taken along line I-I″ of FIG. 3 according to an embodiment of the present disclosure;

FIG. 12 is a cross-sectional view illustrating a sub-pixel including a light emitting element disposed in a display area according to an embodiment of the present disclosure;

FIG. 13 is a diagram illustrating a device to which the display device according to embodiments of the present disclosure is applied;

FIG. 14 is a diagram illustrating a device to which the display device according to embodiments of the present disclosure is applied;

FIG. 15 is a diagram illustrating a device to which the display device according to embodiments of the present disclosure is applied; and

FIG. 16 is a diagram illustrating a device to which the display device according to embodiments of the present disclosure is applied.

### DETAILED DESCRIPTION

The advantages and features of the present disclosure and methods for accomplishing the same will be more clearly understood from embodiments described below with reference to the accompanying drawings. However, the present disclosure is not limited to the following embodiments but may be implemented in various different forms. Rather, the present embodiments will make the disclosure of the present disclosure complete and allow those skilled in the art to completely comprehend the scope of the present disclosure. The present disclosure is only defined within the scope of the accompanying claims.

Shapes, dimensions (e.g., widths, thicknesses, heights, depths, sizes, areas, volumes), ratios, angles, numbers, and the like disclosed in the drawings for describing the embodiments of the present disclosure are exemplary, and the present disclosure is not limited to the illustrated items. Like reference numerals refer to like elements throughout. In addition, in describing the present disclosure, if it is determined that the detailed description of the related known technology may unnecessarily obscure the subject matter of the present disclosure, the detailed description thereof will be omitted or briefly described. The terms such as “comprising”, “including”, “containing”, “consisting of”, “constituted of”, “composed of” and “having” used herein are generally intended to allow other components to be added unless the terms are used with the term such as “only”, “merely”, etc.. References to the singular shall be construed to include the plural unless expressly stated otherwise.

In interpreting a component, it is interpreted to include an error or tolerance range even if there is no separate description.

In the case of a description of a positional relationship, for example, when the positional relationship of two parts is described as ‘on,’ ‘at an upper portion,’ ‘over,’ ‘above,’ ‘at a lower portion,’ ‘beneath,’ ‘below,’ ‘under,’ ‘next to, and the like, one or more other parts may be disposed, interposed or located between the two parts unless a term such as ‘just’, ‘right’, ‘immediately’ or ‘directly’ is used. Furthermore, the terms “left,” “right,” “top,” “bottom, “downward,” “upward,” “upper,” “lower,” and the like refer to an arbitrary frame of reference. The term spatially relative should be understood to include different orientations of the element in use or operation in addition to the orientations shown in the drawings. For example, an element described as “below” or “beneath” another element may be placed “above” another element if the elements shown in the drawings are reversed. Thus, the exemplary term “down” may include both down and up directions.

When describing a temporal contextual relationship, such as “after,” “following,” “subsequent to,” “next to,” or “before,” it may also include non-contiguous cases unless a term such as “just”, “immediately” or “directly” is used.

In the description for the embodiments, the first, second, etc. are used to describe various components, but these components are not limited by these terms. These terms are only used to distinguish one component from another. Therefore, the first component mentioned below may be a second component within the technical spirit of the present disclosure.

Terms such as first, second, A, B, (a), (b), and the like may be used to describe elements of the embodiments of the present specification. Such terms are intended only to distinguish one component from another and are not intended to define the nature, sequence, order, or number of such components.

When a component is described as “connected,” “coupled,” “linked,” “adhered,” or “attached” to another component, it is to be understood that the component may be directly connected, coupled, linked, adhered or attached to the other component, but that there may also be other components “interposed”,“disposed” or “located” between the respective components which may be indirectly connected, coupled, linked, adhered or attached where not specifically stated. It is also to be understood that when a component or layer is described as being “in contact with” or “overlapping” another component or layer, the component or layer may be in direct contact with or directly overlapping the other component or layer, but, unless specifically stated otherwise, still another component or layer may be located, disposed or interposed between these two components or layers so that they are in indirect contact with or indirectly overlapping each other.

It should be understood that the term “at least one” includes all possible combinations of one or more related components. For example, the meaning of “at least one of the first, second, and third components” includes not only the first, second, or third component, but also any combination of two or more of the first, second, and third components.

“First direction,” “second direction,” “third direction,” “X-axis direction,” “Y-axis direction,” and “Z-axis direction” should not be interpreted only as geometric relationships that are perpendicular to each other, but may mean a broader directionality within the range that the configuration of the present specification may function.

The following embodiments may be combined or associated with each other in whole or in part, and various types of interlocking and driving are technically possible. The embodiments may be implemented independently of each other or together in an interrelated relationship.

Hereinafter, preferred embodiments of the present disclosure will be described in detail with reference to the accompanying drawings.

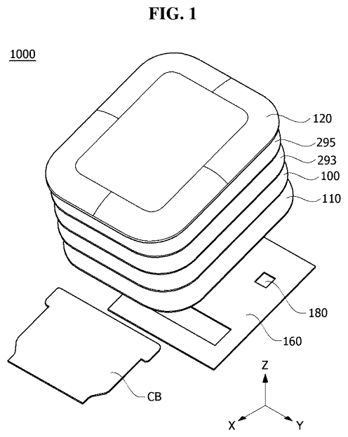

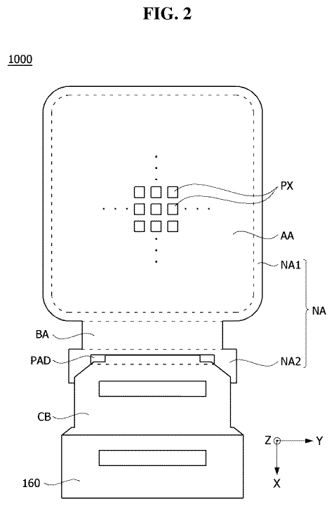

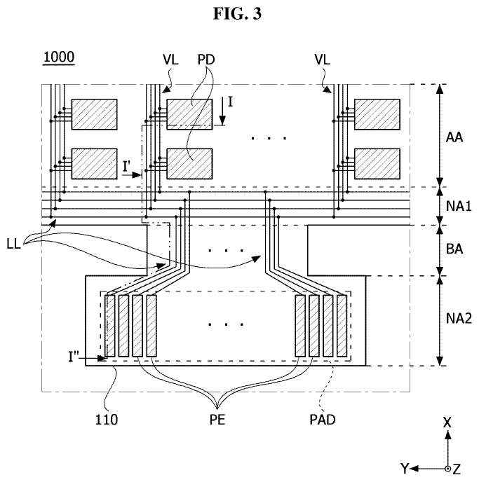

FIG. 1 is an exploded perspective view of the display device according to an embodiment of the present disclosure. FIG. 2 is a plan view illustrating a display device according to an embodiment of the present disclosure. FIG. 3 is an enlarged view illustrating the display device according to an embodiment of the present disclosure.

Referring to FIGS. 1 to 3, a display device 1000 according to an embodiment of the present disclosure may include a display panel 100, a polarizing layer 293, an adhesive layer 295, a cover member 120, a support substrate 110, a flexible circuit board CB, and a printed circuit board 160, but the present disclosure is not limited thereto. For example, one or more of the above-described components or layers can be omitted, integrated or each include one or more sub-components or sub-layers. Alternatively, the display device 1000 can include more or less components or layers than described.

For example, the display device 1000 may include the substrate 110. The substrate 110 may be a member that supports other components of the display device 1000. The substrate 110 may be made of an insulating material. For example, the substrate 110 may be made of glass, a resin, etc. Further, the substrate 110 may be made of a material having flexibility. For example, the substrate 110 may be made of a plastic material having flexibility, such as polyimide (PI), polyethylene terephthalate(PET), polycarbonate(PC), acrylonitrile-butadiene-styrene copolymer(ABS), polymethyl methacrylate(PMMA), polyethylene naphthalate(PEN), polyether sulfone(PES), cyclic olefin copolymer(COC), triacetylcellulose(TAC) film, polyvinyl alcohol(PVA), and polystyrene(PS). However, the embodiments of the present disclosure are not limited thereto.

The display panel 100 may implement information, a video, and/or an image that is provided to a user. For example, the display panel 100 may include a display area AA and a non-display area NA. For example, the substrate 110 may include the display area AA and a non-display area NA. The display area AA and the non-display area NA are not limited to the substrate 110 but can be described throughout the entire display device 1000.

The display area AA may be an area where a video is displayed. The non-display area NDA may be an area outside of the display area DA (for example, in the vicinity of the display area DA or entirely or partly surrounding the display area DA), and may also be referred to as an edge area or a bezel area. The non-display area NDA may include a plurality of adjacent or separate non-display areas. The display area AA may include a plurality of pixels PX. Each of the plurality of pixels PX may be configured of a plurality of sub-pixels (for example, two, three or more). One or a plurality of light emitting elements may be disposed in each of the plurality of sub-pixels. The plurality of light emitting elements may be configured differently depending on a type of the display device 1000. For example, when the display device 1000 is an inorganic light emitting display, the light emitting element may be a inorganic light emitting diode (LED), a micro light emitting diode (μLED), or a mini light emitting diode (mini LED), but the embodiments of the present disclosure are not limited thereto.

The non-display area NA may be an area where no information, image or video is displayed. In the non-display area NA, various wirings and/or circuits for driving the plurality of pixels PX in the display area AA may be disposed. For example, in the non-display area NA, various wirings and/or driving circuits may be mounted and a pad part PAD to which an integrated circuit, a printed circuit, and the like are connected may be disposed, but the embodiments of the present disclosure are not limited thereto.

For example, the driving circuit may be a data driving circuit and/or a gate driving circuit and/or a touch sense driving circuit, but the embodiments of the present disclosure are not limited thereto. Wirings that supply control signals for controlling the driving circuits may be disposed on the display panel 100. For example, the control signal may include various timing signals, which include a clock signal, an input data enable signal, and synchronization signals such as horizontal synchronization signals or vertical synchronization signals, but the embodiments of the present disclosure are not limited thereto. The control signal may be received through the pad part PAD and/or wirings and/or layers. For example, link wirings LL for transmitting signals may be disposed in the non-display area NA. For example, driving components such as the flexible circuit board CB and/or the printed circuit board 160 may be connected to the pad part PAD.

According to the present disclosure, the non-display area NA may include a first non-display area NA1, a bending area BA, and a second non-display area NA2. For example, the first non-display area NA1 may be an area surrounding at least a portion of the display area AA. The bending area BA may be an area extending from at least one of a plurality of sides of the first non-display area NA1 and may be a bendable area. The second non-display area NA2 may be an area extending from the bending area BA along a direction opposite to the first non-display area NA1, and the pad part PAD may be disposed therein. For example, the bending area BA may be in a bent state, and an area of the substrate 110 other than the bending area BA may be in a flat state. In this case, when the bending area BA is bent, the second non-display area NA2 may be positioned on a back surface of the display area AA. However, the embodiments of the present disclosure are not limited thereto.

The display area AA of the substrate 110 or the display device 1000 may be configured in various shapes according to a design of the display device 1000. For example, the display area AA may be configured in a rectangular shape with four corners formed in rounded shapes, but the embodiments of the present disclosure are not limited thereto. In another example, the display area AA may be configured in a rectangular shape with four corners formed in right angle shapes, in a circular shape, in an elliptic shape, in an oval shape, in a polygon shape (e.g., a hexagon) or the like, but the embodiments of the present disclosure are not limited thereto.

According to the present disclosure, a width of the second non-display area NA2 where the plurality of pad electrodes PE are disposed may be larger than a width of the bending area BA where only a plurality of link wirings LL are disposed. Further, a width of the display area AA where the plurality of sub-pixels are disposed may be larger than the width of the bending area BA where the plurality of link wirings LL are disposed. In the figure, the width of the bending area BA is illustrated as being narrower than those of other areas of the substrate 110, but the shape of the substrate 110 including the bending area BA is an example and the embodiments of the present disclosure are not limited thereto.

Referring to FIG. 3, a plurality of pixel driving circuits PD may be disposed in the display area AA. The plurality of pixel driving circuits PD may be circuits for driving the light emitting elements of the plurality of sub-pixels. Each pixel driving circuit PD may drive the driving light-emitting elements of at least one sub-pixel. Each of the plurality of pixel driving circuits PD includes a plurality of transistors including driving transistors, storage capacitors, and the like, and may supply control signals, power, voltages (e.g., high potential voltages, low potential voltages) and driving current to the light emitting elements of one or the plurality of sub-pixels to control light emitting operations of one or the plurality of light emitting elements. For example, the pixel driving circuit PD may include a power wiring, and a signal wiring for controlling light emitting on/off and/or light emitting time of the light emitting element. For example, the plurality of pixel drivers PD may be driving drivers manufactured on a semiconductor substrate using a metal-oxide-silicon field effect transistor (MOSFET) manufacturing process. In the embodiment of the present disclosure, a case where the pixel driving circuit PD is a pixel driver PD has been described by way of example, but the embodiments of the present disclosure are not limited thereto. The driving driver may include the plurality of pixel driving circuits PD and drive the plurality of sub-pixels.

Referring to FIG. 1 together, the flexible circuit board CB and/or the printed circuit board 160 may be disposed below the display panel 100. The flexible circuit board CB and/or the printed circuit board 160 may be disposed at or attached to at least one edge of the display panel 100, but the embodiments of the present disclosure are not limited thereto. One side of the flexible circuit board CB may be attached to the display panel 100 and another side may be attached to the printed circuit board 160, but the embodiments of the present disclosure are not limited thereto. The flexible circuit board CB may be a flexible film, but the embodiments of the present disclosure are not limited thereto. For example, the flexible circuit board CB may alternatively be a flexible flat cable (FFC) or a flexible printed circuit (FPC).

The pad part PAD including the plurality of pad electrodes PE may be disposed in the second non-display area NA2. A driving component including one or more flexible circuit boards (or flexible films) CB and/or printed circuit boards 160 may be attached or bonded to the pad part PAD. The plurality of pad electrodes PE of the pad part PAD may be electrically connected to the one or more flexible circuit boards (or flexible films) CB and transmit various signals or power, voltage, current from the printed circuit boards 160 and/or the flexible circuit boards (or flexible films) CB to the plurality of pixel drivers PD in the display area AA.

The flexible circuit board (or flexible film) CB may be a film in which various components are disposed on a flexible base film. For example, a driving integrated circuit (IC) such as a gate driver IC, a data driver IC or a touch sensing driver IC may be disposed on the flexible circuit board (or flexible film) CB, but the embodiments of the present disclosure are not limited thereto. The driving IC may be a component that processes data and a driving signal for displaying a video. The driving IC may be disposed in a manner such as a chip on glass (COG), a chip on film (COF), a chip on plastic (COP), a chip on plate (COP), or a tape carrier package (TCP) depending on a mounting scheme, but the embodiments of the present disclosure are not limited thereto. The flexible circuit board (or flexible film) CB may be attached or bonded to the plurality of pad electrodes PE through a conductive adhesive layer, but the embodiments of the present disclosure are not limited thereto.

The printed circuit board 160 may be a component that is electrically connected to the one or more flexible circuit boards (or flexible films) CB to supply a signal to the driving IC. The printed circuit board 160 may be disposed on one side of the flexible circuit board (or flexible film) CB and electrically connected to the flexible circuit board (or flexible film) CB. Various components for supplying various signals (or power, voltage, current) to the driving IC may be disposed on the printed circuit board 160. For example, various components such as a timing controller, a power supply, a memory, or a processor may be disposed on the printed circuit board 160. For example, the printed circuit board 160 may include a power management integrated circuit (PMIC), but the embodiments of the present disclosure are not limited thereto.

The printed circuit board 160 may include at least one hole 180, but the embodiments of the present disclosure are not limited thereto. An internal component that detects ambient light, temperature, humidity or the like that may be provided to a plurality of sensors may be disposed in an area corresponding to the at least one hole 180. In one embodiment, a sensor may overlap the hole 180 or may be disposed in the hole 180. For example, the internal component may include an ambient light sensor (ALS), a temperature sensor, a humidity sensor or the like, but the embodiments of the present disclosure are not limited thereto. For example, the hole 180 may be a transparent hole, but the embodiments of the present disclosure are not limited thereto.

Referring to FIG. 1, the polarizing layer 293 may be disposed on the display panel 100. The polarizing layer 293 can prevent or reduce light generated from an external light source from entering the display panel 100 and affecting light emitting elements and the like.

The cover member 120 may be disposed above the polarizing layer 293. The cover member 120 may be a member for protecting the display panel 100. The adhesive layer 295 may be disposed between the polarizing layer 293 and the cover member 120. The cover member 120 may be attached to the display panel 100 by the adhesive layer 295. The adhesive layer 295 may include an optically clear adhesive (OCA), an optically clear resin (OCR), or a pressure sensitive adhesive (PSA), a silicone resin, an epoxy resin, a UV curable resin, a polyimide resin, an acrylate resin, a polyurethane resin, and polydimethylsiloxane (PDMS), but the embodiments of the present disclosure are not limited thereto.

The support substrate 110 may be disposed between the display panel 100 and the printed circuit board 160. The support substrate 110 may reinforce the rigidity of the display panel 100. The support substrate 110 may be a back plate, but the embodiments of the present disclosure are not limited thereto.

The plurality of link wirings LL may be disposed in the non-display area NA. The plurality of link wirings LL may be wirings that transmit various signals (or power, voltage, current) from the one or more flexible circuit boards (or flexible films) CB and/or printed circuit boards 160 to the display area AA. The plurality of link wirings LL may extend from the plurality of pad electrodes PE in the second non-display area NA2 toward the bending area BA and the first non-display area NA1 and be electrically connected to a plurality of driving wirings VL in the display area AA. The plurality of pixel drivers PD may be driven by receiving the signals (or power, voltage, current) from the one or more flexible circuit boards (or flexible films) CB and/or printed circuit boards 160 through the driving wirings VL in the display area AA and the link wirings LL in the non-display area NA.

For example, the plurality of driving wirings VL may be wirings for transmitting the signals (or power, voltage, current) output from the flexible circuit boards (or flexible films) CB and/or the printed circuit boards 160 to the plurality of pixel drivers PD together with the plurality of link wirings LL. The plurality of driving wirings VL may be disposed in the display area AA and electrically connected to each of the plurality of pixel drivers PD. The plurality of driving wirings VL may extend from the display area AA toward the non-display area NA and be electrically connected to the plurality of link wirings LL. Thus, the signals (or power, voltage, current) output from the flexible circuit boards (or flexible films) CB and/or the printed circuit boards 160 may be transmitted to each of the plurality of pixel drivers PD through the plurality of link wirings LL and the plurality of driving wirings VL.

Since the bending area BA is bent, portions of the plurality of link wirings LL may also be bent together. Stress may be concentrated on the portions of the bent link wirings LL and cause cracks in the link wirings LL. Accordingly, the plurality of link wirings LL may be formed of a conductive material having excellent flexibility to reduce cracks when the bending area BA is bent. For example, the plurality of link wirings LL may be formed of a conductive material having excellent flexibility, such as gold (Au), silver (Ag), Copper (Cu) or aluminum (Al), but the embodiments of the present disclosure are not limited thereto. Further, the plurality of link wirings LL may be formed of one of various conductive materials used in the display area AA. For example, the plurality of link wirings LL may be made of, for example, molybdenum (Mo), chromium (Cr), titanium (Ti), nickel (Ni), Gold (Au), aluminum (Al), neodymium (Nd), copper (Cu), an alloy of silver (Ag) and magnesium (Mg), or an alloy thereof, but the embodiments of the present disclosure are not limited thereto. The plurality of link wirings LL may be configured in a multilayer structure including various conductive materials. For example, the plurality of link wirings LL may be configured in a triple layer structure of e.g., titanium (Ti)/aluminum (Al))/titanium (Ti), aluminum (Al)/molybdenum titanium (MoTi)/aluminum (Al), etc., but the embodiments of the present disclosure are not limited thereto.

The plurality of link wirings LL may be configured in various shapes to reduce the stress. At least portions of the plurality of link wirings LL disposed in the bending area BA may extend in the same direction as a direction in which the bending area BA extends or extend in a different direction from the direction in which the bending area BA extends to reduce the stress. For example, when the bending area BA extends in one direction from the first non-display area NA1 toward the second non-display area NA2, at least portions of the link wirings LL disposed in the bending area BA may extend in a direction oblique to the one direction. In another example, at least portions of the plurality of link wirings LL may be configured in various patterns of shapes. For example, the at least portions of the plurality of link wirings LL disposed in the bending area BA may have a shape in which conductive patterns having at least one of a diamond shape, a rhombus shape, a trapezoidal wave shape, a stripe shape, a zigzag shape, a triangular wave shape, a sawtooth wave shape, a sine wave shape, a circular shape, and an omega (Ω) shape are repeatedly disposed, but the embodiments of the present disclosure are not limited thereto. Accordingly, in order to minimize or at least reduce stress concentrated on the plurality of link wirings LL and cracks resulting therefrom, shapes of the plurality of link wirings LL may be various shapes including the above-described shapes, but the embodiments of the present disclosure are not limited thereto.

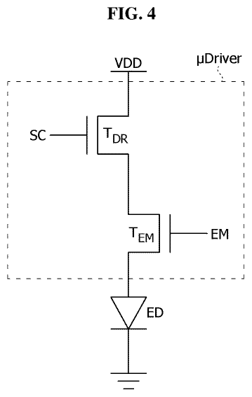

FIG. 4 is a diagram illustrating a circuit structure according to an embodiment of the present disclosure.

Referring to FIG. 4, one light emitting element ED is connected to a micro driver Driver, but the present disclosure is not limited thereto. For example, eight light emitting elements ED may be connected to one micro driver Driver. In another example, 16 light emitting elements ED may be connected to one micro driver Driver or 32 light emitting elements ED or 64 light emitting elements ED may be connected to one micro driver μDriver at the same time. The light emitting element ED may be a micro light emitting element μLED.

The one micro driver μDriver may include a driving transistor T_{DR} and a light emitting transistor T_{EM}, but the embodiments of the present disclosure are not limited thereto.

For example, the driving transistor T_{DR} may have a first electrode to which a high-potential power supply voltage VDD is applied, a second electrode to which a first electrode of the light emitting transistor T_{EM} is connected, and a gate electrode to which a scan signal SC is applied. The scan signal SC applied to the gate electrode of the driving transistor T_{DR} may be a direct current voltage, and a fixed reference voltage Vref may be applied for each frame or each sub-frame, but the embodiments of the present disclosure are not limited thereto. Alternatively, depending on the type of the driving transistor, the first electrode thereof may be applied with a low-potential power supply.

The light emitting transistor T_{EM} may have a first electrode to which the second electrode of the driving transistor T_{DR} is connected, a second electrode to which the light emitting element ED is connected, and a gate electrode to which a light emitting signal EM is applied. The light emitting signal EM applied to the gate electrode of the light emitting transistor T_{EM} may be a pulse width modulation (PWM) signal that varies for each frame, but the embodiments of the present disclosure are not limited thereto. Alternatively, the emission signal EM applied to the gate electrode of the light-emitting transistor TEM may be a pulse width modulation signal that varies every sub-frame, and embodiments of the present disclosure are not limited thereto.

A first electrode of the light emitting element ED may be connected to the second electrode of the light emitting transistor T_{EM}, and a second electrode of the light emitting element ED may be connected to the ground. For example, the first electrode of the light emitting element ED may be an anode electrode, and the second electrode of the light emitting element ED may be a cathode electrode, but the embodiments of the present disclosure are not limited thereto. Alternatively, the first electrode CE1 may be a cathode electrode, and the second electrode CE2 may be an anode electrode.

Each of the driving transistor T_{D}R and the light emitting transistor T_{EM} may be an n-type transistor or a p-type transistor.

In the micro driver μDriver, the driving transistor T_{DR} may be turned on by the scan signal SC applied from a timing controller T-CON, and the light emitting transistor T_{EM} may be turned on by the light emitting signal EM. Accordingly, a driving current is applied to the light emitting element ED via the driving transistor T_{D}R and the light emitting transistor T_{EM} by the high-potential power supply voltage VDD applied to the first electrode of the driving transistor T_{DR}, so that the light emitting element ED can emit light.

FIG. 5 is a diagram illustrating a plurality of touch blocks disposed on the in-cell touch display panel according to an embodiment of the present disclosure.

Referring to FIG. 5, the in-cell touch display panel according to the embodiment of the present disclosure may include a plurality of touch units where each touch unit includes k touch groups of a plurality of touch groups TG1, TG2, . . . , TG(n+3) (n is a positive integer greater than or equal to 2, for example, n is equal to 13, without limited thereto) disposed in the display area AA of the display device 1000, wherein k is an integer greater, for example, k is equal to 4, without limited thereto. Each of the touch groups TG1, TG2, . . . , TG(n+3) may include a plurality of pixels PX that are N*M (M and N are positive integers greater than or equal to 2, for example, N is equal to 2, and M is equal to 2, without limited thereto) pixels PX.

For example, a touch unit may include touch groups TG comprising a first touch group TG1, a second touch group TG2 adjacent to the first touch group TG1 in a row direction (e.g., a first direction), a third touch group TG3 adjacent to the first touch group TG1 in a column direction (e.g., a second direction), and a fourth touch group TG4 adjacent to the second touch group TG2 in the column direction. Further, the touch group of a touch unit may include an n-th touch group TG(n), an (n+1)-th touch group TG(n+1) adjacent to the n-th touch group TG(n) in the row direction, an (n+2)-th touch group TG(n+2) adjacent to the n-th touch group TG(n) in the column direction, and an (n+3)-th touch group TG(n+3) adjacent to the (n+1)-th touch group TG(n+1) in the column direction. The embodiments of the present disclosure are not limited thereto.

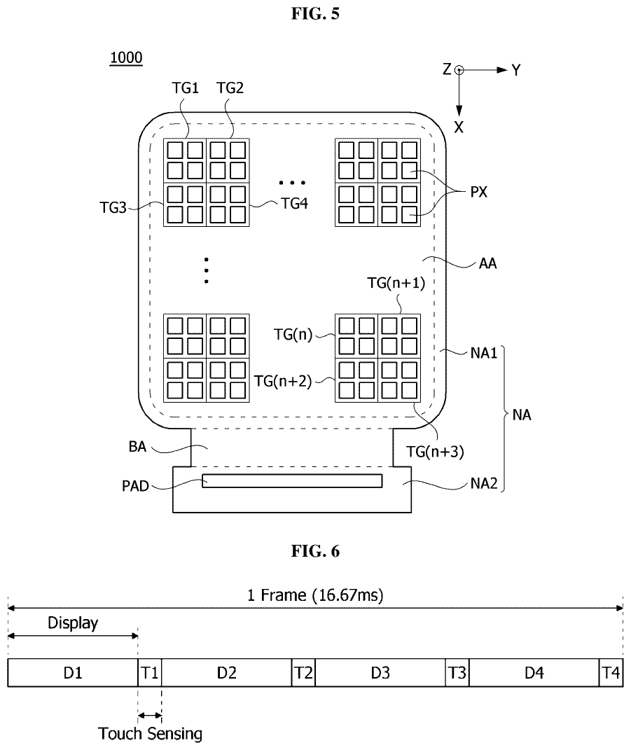

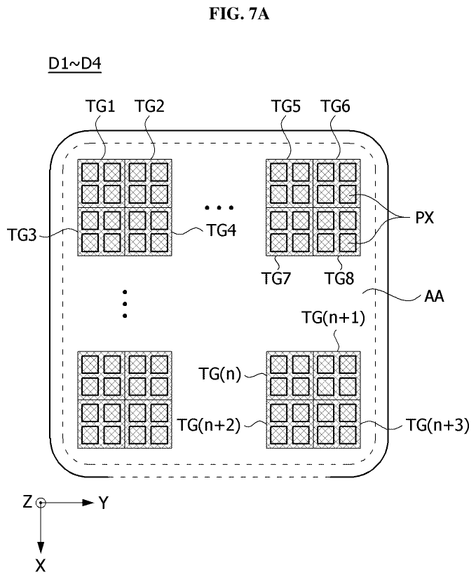

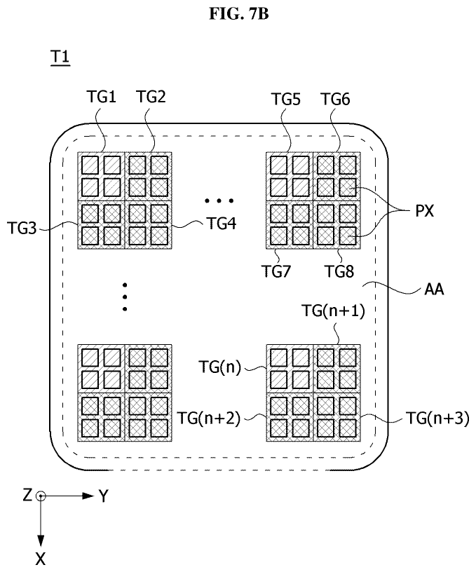

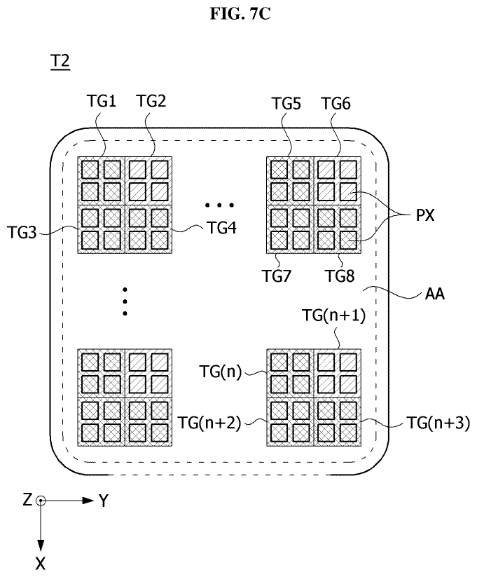

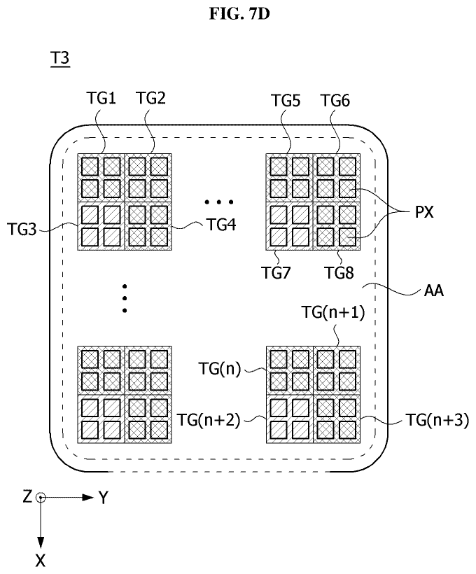

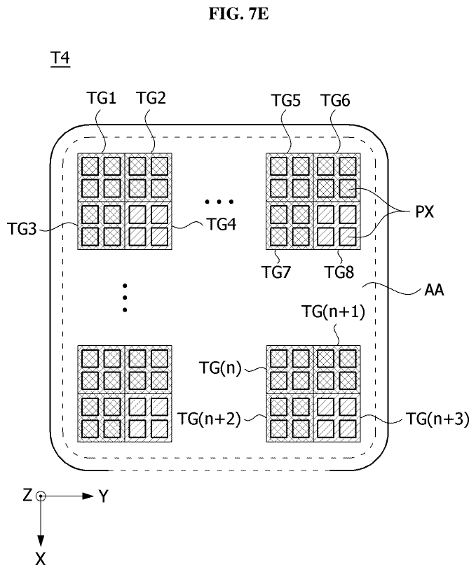

FIG. 6 is a diagram illustrating a method of driving an in-cell touch display panel according to an embodiment of the present disclosure. FIGS. 7A to 7E are diagrams illustrating the method of driving an in-cell touch display panel according to an embodiment of the present disclosure.

Referring to FIGS. 6 and 7A to 7E, in the in-cell touch display panel according to the embodiment of the present disclosure, some of the pixel electrodes for display may be disposed integrally with a touch electrode for touch sensing in an in-cell touch manner. Therefore, the touch group may be driven with display driving for image output and touch sensing driving temporally divided for one frame (e.g., 16.67 ms) by units of touch groups.

The in-cell touch display panel may be driven in display periods D1, D2, D3, and D4 and touch sensing periods T1, T2, T3, and T4 during one frame period, but the present disclosure is not limited thereto. With reference to the number of touch groups included in a touch unit, one frame may be divided into more or less than four display periods and touch sensing periods.

For division of the display periods D1, D2, D3, and D4 and the touch sensing periods T1, T2, T3, and T4, the periods may be disposed so that the touch sensing driving is performed in a period other than a period in which a display driving signal is supplied to the plurality of touch groups TG1, TG2, . . . , TG(n+3). For example, the first touch sensing period T1 may be disposed after the first display period D1, and the second display period D2 may be disposed after the first touch sensing period T1. The embodiments of the present disclosure are not limited thereto.

In the first to fourth display periods D1, D2, D3, and D4, all of the plurality of touch groups TG1, TG2, . . . , TG(n+3) output a video and do not perform touch sensing in response to the display driving signal, as illustrated in FIG. 7A.

In the first touch sensing period T1, the first touch group TG1, the fifth touch group TG5, . . . , the n-th touch group TG(n) among the plurality of touch groups TG1, TG2, . . . , TG(n+3) are driven with the touch sensing driving, as illustrated in FIG. 7B. Each touch group driven during the first sensing period T1 is disposed in the same location within each touch unit. For example, in the first touch sensing period, the first touch group TG1, the fifth touch group TG5, . . . , the n-th touch group TG(n) are all located in the upper left quadrant of the touch unit. The first touch group TG1, the fifth touch group TG5, . . . , the n-th touch group TG(n), may all be considered the “first touch group” of their respective touch unit. In the first touch sensing period, the touch groups other than the first touch group TG1, the fifth touch group TG5, . . . , the n-th touch group TG(n) may receive the display drive signal from the pixel driver PD and output an image as in the display period D1, D2, D3, and D4, but are not sensed for touch. For example, the common electrodes of the touch groups that display the image during the first touch sensing period may receive a common voltage. In contrast, common electrodes of the first touch group TG1, the fifth touch group TG5, . . . , the n-th touch group TG(n) receive the touch driving signal to sense touch during the first touch sensing period. The embodiments of the present disclosure are not limited thereto.

In the second touch sensing period T2, the second touch group TG2, the sixth touch group TG6, . . . , the (n+1)-th touch group TG(n+1) among the plurality of touch groups TG1, TG2, . . . , TG(n+3) may be driven with the touch sensing driving, as illustrated in FIG. 7C. For example, in the second touch sensing period, the second touch group TG2, the sixth touch group TG6, . . . , the (n+1)-th touch group TG(n+1) are all located in the upper right quadrant of the touch unit. The second touch group TG2, the sixth touch group TG6, . . . , the (n+1)-th touch group TG(n+1) may all be considered the “second touch group” of their respective touch unit. In the second touch sensing period, the touch groups other than the second touch group TG2, the sixth touch group TG6, . . . , the (n+1)-th touch group TG(n+1) may receive the display driving signal and output an image as in the display periods D1, D2, D3, and D4, but are not sensed for touch. For example, the common electrodes of the touch groups that display the image during the second touch sensing period may receive a common voltage. In contrast, common electrodes of the second touch group TG2, the sixth touch group TG6, . . . , the (n+1)-th touch group TG(n+1) receive the touch driving signal to sense touch during the second touch sensing period. The embodiments of the present disclosure are not limited thereto.

In the third touch sensing period T3, the third touch group TG3, the seventh touch group TG7, . . . , the (n+2)-th touch group TG(n+2) among the plurality of touch groups TG1, TG2, . . . , TG(n+3) may be driven with the touch sensing driving, as illustrated in FIG. 7D. For example, in the third touch sensing period, the third touch group TG3, the seventh touch group TG7, . . . , the (n+2)-th touch group TG(n+2) are all located in the lower left quadrant of the touch unit. The third touch group TG3, the seventh touch group TG7, . . . , the (n+2)-th touch group TG(n+2) may all be considered the “third touch group” of their respective touch unit. In the third touch sensing period, the touch groups other than the third touch group TG3, the seventh touch group TG7, . . . , the (n+2)-th touch group TG(n+2) may receive the display driving signal and output an image as in the display periods D1, D2, D3, and D4, but are not sensed. For example, the common electrodes of the touch groups that display the image during the third touch sensing period may receive a common voltage. In contrast, the common electrodes of the third touch group TG3, the seventh touch group TG7, . . . , the (n+2)-th touch group TG(n+2) receive the touch driving signal to sense touch during the third touch sensing period. The embodiments of the present disclosure are not limited thereto.

In the fourth touch sensing period T4, the fourth touch group TG4, the eighth touch group TG8, . . . , the (n+3)-th touch group TG(n+3) among the plurality of touch groups TG1, TG2, . . . , TG(n+3) may be driven with the touch sensing driving, as illustrated in FIG. 7E. For example, in the fourth touch sensing period, the fourth touch group TG4, the eighth touch group TG8, . . . , and the (n+3)-th touch group TG(n+3) are all located in the lower right quadrant of the touch unit. The fourth touch group TG4, the eighth touch group TG8, . . . , and the (n+3)-th touch group TG(n+3) may all be considered the “fourth touch group” of their respective touch unit. In the fourth touch sensing period, the touch groups other than the fourth touch group TG4, the eighth touch group TG8, . . . , the (n+3)-th touch group TG(n+3) may receive the display driving signal and output an image as in the display periods D1, D2, D3, and D4, but are not sensed. For example, the common electrodes of the touch groups that display the image during the fourth touch sensing period may receive a common voltage. In contrast, the common electrodes of the fourth touch group TG4, the eighth touch group TG8, . . . , the (n+3)-th touch group TG(n+3) receive the touch driving signal to sense touch during the fourth touch sensing period. The embodiments of the present disclosure are not limited thereto.

The above description shows an example of sequentially driving each touch group of a touch unit with the touch sensing drive in a clockwise direction starting from the upper left quadrant of the touch unit, but the embodiments of the present disclosure are not limited thereto. Alternatively, each touch group of a touch unit may be sequentially driven in a clockwise direction starting from any other quadrant in the touch unit with the touch sensing drive. Alternatively, the touch groups in the touch unit may be driven with the touch sensing drive in any order, out of order or randomly starting from any touch group in any quadrant in a touch unit until all touch groups are driven with the touch sensing drive.

One frame is divided into the touch sensing periods and areas for touch sensing, making it possible to increase the accuracy of touch sensing and to continuously display images in other touch groups that do not perform touch sensing during the touch sensing period, resulting in improved display quality.

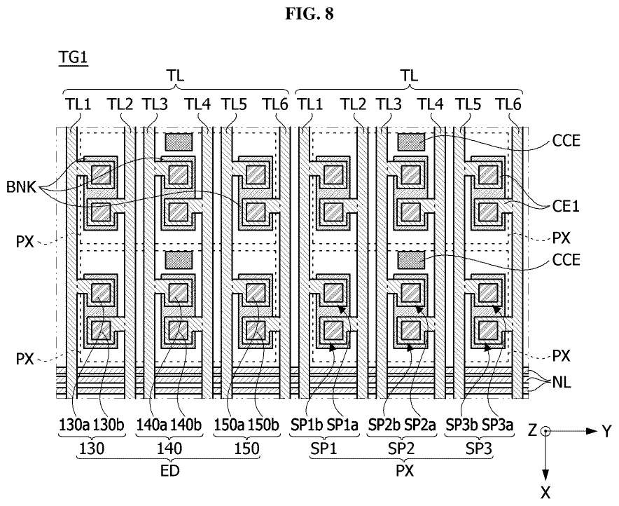

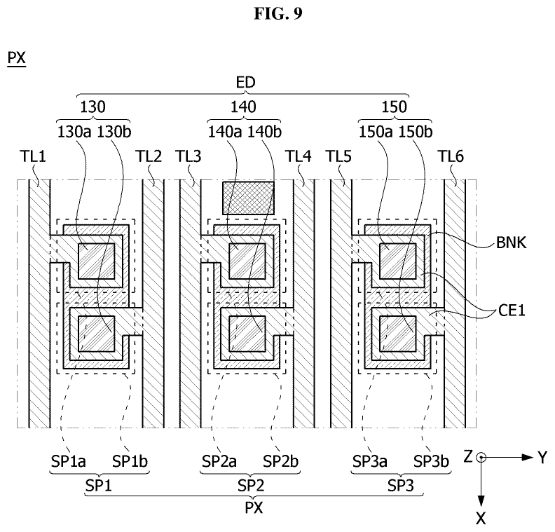

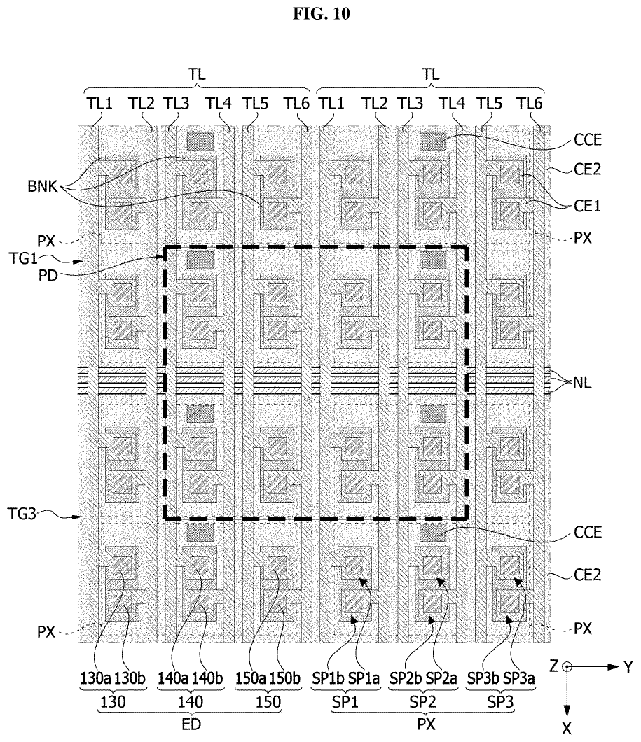

FIG. 8 is an enlarged view of the touch group according to an embodiment of the present disclosure. FIG. 9 is an enlarged view of pixels disposed in the touch group according to an embodiment of the present disclosure. FIG. 10 is an enlarged view of the touch group according to an embodiment of the present disclosure.

In FIGS. 8 and 9, a plurality of signal wirings TL, a plurality of communication wirings NL, a plurality of first electrodes CE1, a plurality of banks BNK, and the plurality of light emitting elements ED are illustrated, but the embodiments of the present disclosure are not limited thereto. FIG. 10 is an enlarged plan view of FIG. 8 in which a plurality of second electrodes CE2 are additionally disposed.

Referring to FIGS. 8 and 9, the plurality of (e.g., four) pixels PX each including the plurality of (e.g., three) sub-pixels may be disposed in the first touch group TG1 disposed in the display area AA. Each of the plurality of sub-pixels disposed in the first touch group TG1 may include the light emitting element ED to independently emit light. The plurality of sub-pixels may form a plurality of rows and a plurality of columns and may be disposed in a matrix form of N*M, but the embodiments of the present disclosure are not limited thereto. Alternatively, sub-pixels may be disposed in Pentile form, diamond form, diamond-like form, etc.

The plurality of sub-pixels may include a first sub-pixel SP1, a second sub-pixel SP2, and a third sub-pixel SP3. For example, one of the first sub-pixel SP1, the second sub-pixel SP2, and the third sub-pixel SP3 may be a red sub-pixel, another may be a green sub-pixel, and the last one may be a blue sub-pixel. The types of the plurality of sub-pixels are examples, and the embodiments of the present disclosure are not limited thereto. For example, the plurality of sub-pixels may alternatively include a different number of sub-pixels emitting light of colors from a different color system such as CMYK.

Each of the plurality of pixels PX may include at least one first sub-pixel SP1, at least one second sub-pixel SP2, and at least one third sub-pixel SP3. For example, one pixel PX may include the pair of first sub-pixels SP1, the pair of second sub-pixels SP2, and the pair of third sub-pixels SP3. The pair of first sub-pixels SP1 may include a (1-1)-th sub-pixel SPla and a (1-2)-th sub-pixel SP1b. The pair of second sub-pixels SP2 may include a (2-1)-th sub-pixel SP2a and a (2-2)-th sub-pixel SP2b. The pair of third sub-pixels SP3 may include a (3-1)-th sub-pixel SP3a and a (3-2)-th sub-pixel SP3b. For example, one pixel PX may include the (1-1)-th sub-pixel SPla and the (1-2)-th sub-pixel SP1b, the (2-1)-th sub-pixel SP2a and the (2-2)-th sub-pixel SP2b, and the (3-1)-th sub-pixel SP3a and the (3-2)-th sub-pixel SP3b, but the embodiments of the present disclosure are not limited thereto.

The plurality of sub-pixels forming one pixel PX may be arranged in various ways. For example, in the one pixel PX, a pair of first sub-pixels SP1 may be disposed in the same column, a pair of second sub-pixels SP2 may be disposed in the same column, and a pair of third sub-pixels SP3 may be disposed in the same column. The first sub-pixel SP1, the second sub-pixel SP2, and the third sub-pixel SP3 may be disposed in the same row. The number and arrangement of the plurality of sub-pixels constituting one pixel PX are examples, and the embodiments of the present disclosure are not limited thereto. Alternatively, in the one pixel PX, a pair of first sub-pixels SP1 may be disposed in the same row, a pair of second sub-pixels SP2 may be disposed in the same row, and a pair of third sub-pixels SP3 may be disposed in the same row. The first sub-pixel SP1, the second sub-pixel SP2, and the third sub-pixel SP3 may be disposed in the same column.

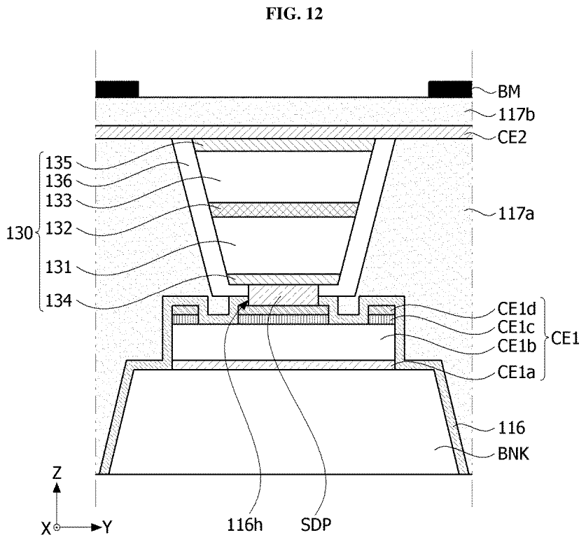

The plurality of signal wirings TL may be disposed in an area between the plurality of sub-pixels. The plurality of signal wirings TL may extend in a column direction between the plurality of sub-pixels. The plurality of signal wirings TL may be wirings that transmit an anode voltage from the pixel driver PD to the plurality of sub-pixels. For example, the plurality of signal wirings TL may be electrically connected to the plurality of pixel drivers PD and the first electrodes CE1 of the plurality of sub-pixels. The anode voltage output from the pixel driver PD may be transmitted to the first electrodes CE1 of the plurality of sub-pixels through the plurality of signal wirings TL. For example, the first electrode CE1 may be an electrode electrically connected to an anode electrode 134 (see FIG. 12) of the light emitting element ED. Accordingly, the anode voltage from the signal wiring TL may be transmitted to the anode electrode 134 of the light emitting element ED through the first electrode CE1.

Therefore, it is possible to simplify a structure of the display device 1000 by using the pixel driver PD in which a plurality of pixel circuits are integrated, instead of forming a plurality of transistors and storage capacitors in each of the plurality of sub-pixels. Further, since circuits disposed in each of the plurality of sub-pixels are integrated in one pixel driver PD, it is possible to achieve high-efficiency and low-power driving. The fact that the circuits disposed in each of the plurality of sub-pixels SP are integrated in the one pixel driver PD means that a plurality of pixel circuits capable of driving the plurality of light emitting elements ED are included in the pixel driver PD. The plurality of light emitting elements ED may be driven by the one pixel driver PD in which the plurality of pixel circuits are integrated. For example, the (1-1)-th light-emitting element 130a, the (2-1)-th light-emitting element 140a, and the (3-1)-th light-emitting element 150a may be driven by one pixel driving circuit PD in which a plurality of pixel circuits are integrated. For example, the (1-2)-th light-emitting element 130b, the (2-2)-th light-emitting element 140b, and the (3-2)-th light-emitting element 150b may be driven by one pixel driving circuit PD in which a plurality of pixel circuits are integrated.

The plurality of signal wirings TL may include for example a first signal wiring TL1, a second signal wiring TL2, a third signal wiring TL3, a fourth signal wiring TL4, a fifth signal wiring TL5, and a sixth signal wiring TL6. The first signal wiring TL1 and the second signal wiring TL2 may be electrically connected to the respective first sub-pixels SP1 in the pair. The third signal wiring TL3 and the fourth signal wiring TL4 may be electrically connected to the respective second sub-pixels SP2 in the pair. The fifth signal wiring TL5 and the sixth signal wiring TL6 may be electrically connected to the respective third sub-pixels SP3 in the pair. Embodiments of the present disclosure are not limited thereto.

The first signal wiring TL1 may be disposed on one side (e.g., a first side) of the pair of first sub-pixels SP1, and the second signal wiring TL2 may be disposed on another side (e.g., a second side) of the pair of first sub-pixels SP1. The first signal wiring TL1 may be electrically connected to the first electrode CE1 of one of the first sub-pixels SP1 in the pair, for example, the (1-1)-th sub-pixel SP1a. The second signal wiring TL2 may be electrically connected to the first electrode CE1 of the other of the first sub-pixels SP1 in the pair, for example, the (1-2)-th sub-pixel SP1b. Embodiments of the present disclosure are not limited thereto.

The third signal wiring TL3 may be disposed on one side (e.g., a first side) of the pair of second sub-pixels SP2, and the fourth signal wiring TL4 may be disposed on another side (e.g., a second side) of the pair of second sub-pixels SP2. For example, the third signal wiring TL3 may be disposed adjacent to the second signal wiring TL2. The third signal wiring TL3 may be electrically connected to the first electrode CE1 of one of the second sub-pixels SP2 in the pair, for example, the (2-1)-th sub-pixel SP2a. The fourth signal wiring TL4 may be electrically connected to the first electrode CE1 of the other of the second sub-pixels SP2 in the pair, for example, the (2-2)-th sub-pixel SP2b. Embodiments of the present disclosure are not limited thereto.

The fifth signal wiring TL5 may be disposed on one side (e.g., a first side) of the pair of third sub-pixels SP3, and the sixth signal wiring TL6 may be disposed on another side (e.g., a second side) of the pair of third sub-pixels SP3. For example, the fifth signal wiring TL5 may be disposed adjacent to the fourth signal wiring TL4. The sixth signal wiring TL6 may be disposed adjacent to the first signal wiring TL1 connected to the adjacent pixel PX. The fifth signal wiring TL5 may be electrically connected to the first electrode CE1 of one of the third sub-pixels SP3 in the pair, for example, the (3-1)-th sub-pixel SP3a. The sixth signal wiring TL6 may be electrically connected to the first electrode CE1 of the other of the third sub-pixels SP3 in the pair, for example, the (3-2)-th sub-pixel SP3b.

The plurality of signal wirings TL may be made of a conductive material. For example, the plurality of signal wirings TL may be made of a conductive material such as titanium (Ti), aluminum (Al), copper (Cu), molybdenum (Mo), nickel (Ni), chromium (Cr), indium tin oxide (ITO), indium zinc oxide (IZO), indium gallium oxide (IGO) or indium gallium zinc oxide (IGZO), but the embodiments of the present disclosure are not limited thereto. For example, the plurality of signal wirings TL may be made in a multilayer structure of conductive materials. For example, the plurality of signal wirings TL may be made of a multilayer structure of titanium (Ti)/aluminum (Al)/titanium (Ti)/indium tin oxide (ITO), indium tin oxide (ITO)/aluminum (Al)/indium tin oxide (ITO), ITO/APC(Ag/Pd/Cu)/ITO etc. but the embodiments of the present disclosure are not limited thereto.

The plurality of communication wirings NL may be disposed in an area between the plurality of touch groups TG. The plurality of communication wirings NL may be disposed to extend in a row direction in an area between the plurality of touch groups TG. The plurality of communication wirings NL may be disposed in an area between the plurality of second electrodes CE2 and may not overlap the plurality of second electrodes CE2. For example, the plurality of communication wirings NL may be wirings that are used for short-range communication such as near field communication (NFC), Bluetooth communication. The plurality of communication wirings NL may function as antennas. For example, the plurality of communication wirings NL may be a plurality of connection wirings or the like, but the embodiments of the present disclosure are not limited thereto.

According to the present disclosure, the bank BNK may be disposed in each of the plurality of sub-pixels. The plurality of banks BNK may be structures on which the plurality of light emitting elements ED are seated. The plurality of banks BNK may guide positions of the plurality of light emitting elements ED in a transfer process for transferring the plurality of light emitting elements ED to the display device 1000. The plurality of light emitting elements ED may be transferred onto the plurality of banks BNK in a transfer process for the plurality of light emitting elements ED. The plurality of banks BNK may be bank patterns, structures, or the like, but the embodiments of the present disclosure are not limited thereto.

The bank BNK of the first sub-pixel SP1, the bank BNK of the second sub-pixel SP2, and the bank BNK of the third sub-pixel SP3 may be disposed apart from each other. The bank BNK of the first sub-pixel SP1, the bank BNK of the second sub-pixel SP2, and the bank BNK of the third sub-pixel SP3 may be configured to be separated. Thus, the banks BNK of the first sub-pixel SP1, the second sub-pixel SP2, and the third sub-pixel SP3 to which different types of light emitting elements ED are transferred can be easily identified.

The bank BNK of the (1-1)-th sub-pixel SP1a and the bank BNK of the (1-2)-th sub-pixel SP1b may be connected to each other or may be formed to be spaced apart or separated from each other. For example, the bank BNK of the (1-1)-th sub-pixel SP1a and the bank BNK of the (1-2)-th sub-pixel SP1b in which light emitting elements ED of the same type are disposed may be connected to each other or may be spaced apart or separated from each other in consideration of design of transfer process requirements or the like. Further, the bank BNK of the (2-1)-th sub-pixel SP2a and the bank BNK of the (2-2)-th sub-pixel SP2b may be connected to each other or may be formed to be spaced apart or separated from each other. The bank BNK of the (3-1)-th sub-pixel SP3a and the bank BNK of the (3-2)-th sub-pixel SP3b may be connected to each other or may be formed to be spaced apart or separated from each other. Thus, the bank BNK of the pair of first sub-pixels SP1, the bank BNK of the pair of second sub-pixels SP2 and the bank BNK of the pair of third sub-pixels SP3 may be formed in various ways, and the embodiments of the present disclosure are not limited thereto.

For example, the plurality of banks BNK may be formed of an organic insulating material. The plurality of banks BNK may be configured of a single layer or a multi-layer of an organic insulating material. For example, the plurality of banks BNK may be formed of a benzocyclobutene resin, a photosensitive polymer, a photo resist, a polyimide (PI), a photo acryl-based material, or the like, but the embodiments of the present disclosure are not limited thereto.

The first electrode CE1 may be disposed on each of the plurality of sub-pixels. The first electrode CE1 may be disposed on the bank BNK. The first electrode CE1 may be electrically connected to one of the plurality of signal wirings TL. At least a portion of the first electrode CE1 may extend outside the bank BNK and be electrically connected to the signal wiring TL most adjacent to the first electrode CE1. For example, a portion of the first electrode CE1 of the (1-1)-th sub-pixel SP1a may extend to one side of the (1-1)-th sub-pixel SP1a and be electrically connected to the first signal wiring TL1, and a portion of the first electrode CE1 of the (1-2)-th sub-pixel SP1b may extend to the other side of the (1-2)-th sub-pixel SP1b and be electrically connected to the second signal wiring TL2. A portion of the first electrode CE1 of the (2-1)-th sub-pixel SP2a may extend to one side of the (2-1)-th sub-pixel SP2a and be electrically connected to the third signal wiring TL3, a portion of the first electrode CE1 of the (2-2)-th sub-pixel SP2b may extend to the other side of the (2-2)-th sub-pixel SP2b and be electrically connected to the fourth signal wiring TL4, a portion of the first electrode CE1 of the (3-1)-th sub-pixel SP3a may extend to one side of the (3-1)-th sub-pixel SP3a and be electrically connected to the fifth signal wiring TL5, and a portion of the first electrode CE1 of the (3-2)-th sub-pixel SP3b may extend to the other side of the (3-2)-th sub-pixel SP3b and be electrically connected to the sixth signal wiring TL6. Embodiments of the present disclosure are not limited thereto.

The first electrode CE1 may be electrically connected to the anode electrode 134 of the light emitting element ED, to transmit the anode voltage from the pixel driver PD to the light emitting element ED through the signal wiring TL. Different voltages may be applied to the first electrodes CE1 of the plurality of sub-pixels depending on a displayed video. For example, different voltages may be applied to the first electrodes CE1 of the plurality of sub-pixels. Thus, the first electrode CE1 may be a pixel electrode and the embodiments of the present disclosure are not limited thereto. Alternatively, the first electrode CE1 may be a common electrode, and the second electrode CE2 may be a pixel electrode.

The first electrode CE1 may be formed of a conductive material. For example, the first electrode CE1 may be formed integrally with the plurality of signal wirings TL. For example, the first electrode CE1 may be made of the same or substantially the same or different conductive material as the plurality of signal wirings TL, but the embodiments of the present disclosure are not limited thereto. For example, the first electrode CE1 may be made of a conductive material such as titanium (Ti), aluminum (Al), copper (Cu), molybdenum (Mo), nickel (Ni), chromium (Cr), indium tin oxide (ITO), indium zinc oxide (IZO), indium gallium oxide (IGO) or indium gallium zinc oxide (IGZO), but the embodiments of the present disclosure are not limited thereto. In another example, the first electrode CE1 may be configured of a multilayer structure of conductive materials. For example, the plurality of first electrodes CE1 may be configured of a multilayer structure of titanium (Ti)/aluminum (Al)/titanium (Ti)/indium tin oxide (ITO), indium tin oxide (ITO)/aluminum (Al)/indium tin oxide (ITO), ITO/APC/ITO, (Ag/MoTi) etc., but the embodiments of the present disclosure are not limited thereto.

The light emitting element ED may be disposed in each of the plurality of sub-pixels. The plurality of light emitting elements ED may be light emitting diodes (LEDs), mini light emitting diodes (mini LEDs) or micro light emitting diodes (LED), but the embodiments of the present disclosure are not limited thereto. The plurality of light emitting elements ED may be disposed on the bank BNK and the first electrode CE1. The plurality of light emitting elements ED may be disposed on the first electrode CE1 and may be electrically connected to the first electrode CE1. Accordingly, the light emitting element ED may receive the anode voltage from the pixel driver PD through the signal wiring TL and the first electrode CE1 to emit light.

The plurality of light emitting elements ED may include a first light emitting element 130, a second light emitting element 140, and a third light emitting element 150. The first light emitting element 130 may be disposed in the first sub-pixel SP1. The second light emitting element 140 may be disposed in the second sub-pixel SP2. The third light emitting element 150 may be disposed in the third sub-pixel SP3. For example, one of the first light emitting element 130, the second light emitting element 140, and the third light emitting element 150 may be a red light emitting element, another may be a green light emitting element, and the last one may be blue light emitting element. However, the embodiments of the present disclosure are not limited thereto. Accordingly, red light, green light, and blue light emitted from the plurality of light emitting elements ED may be combined to implement light with various colors including white. The numbers and types of the plurality of light emitting elements ED are examples, and the embodiments of the present disclosure are not limited thereto. For example, the plurality of sub-pixels may alternatively include a different number of sub-pixels emitting light of colors from a different color system such as CMYK.

The first light emitting element 130 may include a (1-1)-th light emitting element 130a disposed in the (1-1)-th sub-pixel SP1a and a (1-2)-th light emitting element 130b disposed in the (1-2)-th sub-pixel SP1b. The second light emitting element 140 may include a (2-1)-th light emitting element 140a disposed in the (2-1)-th sub-pixel SP2a and a (2-2)-th light emitting element 140b disposed in the (2-2)-th sub-pixel SP2b. The third light emitting element 150 may include a (3-1)-th light emitting element 150a disposed in the (3-1)-th sub-pixel SP3a and a (3-2)-th light emitting element 150b disposed in the (3-2)-th sub-pixel SP3b. Embodiments of the present disclosure are not limited thereto.

Referring to FIG. 10, the second electrode CE2 may be disposed on each of the plurality of sub-pixels. The second electrodes CE2 may be disposed on the light emitting elements ED. The second electrodes CE2 may be electrically connected to the pixel drivers PD through a plurality of contact electrodes CCE.

For example, the second electrode CE2 may be electrically connected to a cathode electrode 135 (see FIG. 12) of the light emitting element ED to transmit a cathode voltage from the pixel driver PD to the light emitting element ED. The same cathode voltage may be applied to the second electrodes CE2 of the plurality of sub-pixels. For example, the same voltage may be applied to the second electrodes CE2 of the plurality of sub-pixels and the cathode electrodes 135 of the light emitting elements ED. Thus, the second electrode CE2 may be a common electrode. Alternatively, the first electrode CE1 may be a common electrode and the second electrode CE2 may be a pixel electrode.

At least some of the plurality of sub-pixels may share the second electrode CE2. At least some of the second electrodes CE2 of the plurality of sub-pixels may be electrically connected to each other. Since the same voltage is applied to the second electrodes CE2, the second electrodes CE2 of at least some of the sub-pixels may be used in a shared manner. For example, the second electrodes CE2 of at least some of the plurality of pixels PX disposed in the same row may be connected to each other. For example, one second electrode CE2 may be disposed in the plurality of pixels PX. One second electrode CE2 may be disposed for n sub-pixels, wherein n is an integer larger than one.

For example, some of the second electrodes CE2 of the plurality of sub-pixels may be disposed apart or separated from each other. For example, the second electrodes CE2 connected to the N*M pixels PX included in the first touch group TG1 and the second electrodes CE2 connected to the N*M pixels PX included in the other adjacent touch groups TG2 and TG3 may be disposed apart or separated. For example, the second electrodes CE2 disposed in the first touch group TG1 may be disposed apart from the second electrodes CE2 disposed in the third touch group TG3 with a plurality of communication wirings NL extending in the row direction interposed or disposed therebetween. Thus, the number of the plurality of sub-pixels may be larger than the number of the plurality of second electrodes CE2. The embodiments of the present disclosure are not limited thereto.

Referring to FIG. 10, the plurality of communication wirings NL may be disposed in an area between the plurality of second electrodes CE2 and may be non-overlapping with the plurality of second electrodes CE2. Accordingly, the second electrode CE2 used as a touch electrode of the first touch group TG1 and the second electrode CE2 used as a touch electrode of the third touch group TG3 may be arranged to be spaced apart from each other. The pixel driver PD may be electrically connected to the second electrode CE2 of the first touch group TG1 and the second electrode CE2 of the third touch group TG3 through the plurality of contact electrodes CCE. Here, the second electrode CE2 of the first touch group TG1 may be a first common electrode. The second electrode CE2 of the third touch group TG3 may be a second common electrode, but is not necessarily limited thereto. For example, the second common electrode may be the second electrode CE2 of the second touch group TG2. When the second electrode CE2 of the second touch group TG2 is the second common electrode, the second electrode CE2 of the third touch group TG3 may be the third common electrode, and the second electrode CE2 of the fourth touch group TG4 may be the fourth common electrode, but is not necessarily limited thereto. The pixels connected to the second electrode CE2 of the first touch group TG1 may be first pixels. The pixels connected to the second electrode CE2 of the third touch group TG3 may be second pixels, but is not necessarily limited thereto. For example, the second pixels may be pixels connected to the second electrode CE2 of the second touch group TG2. When the pixels connected to the second electrode CE2 of the second touch group TG2 are second pixels, the pixels connected to the second electrode CE2 of the third touch group TG3 may be third pixels, and the pixels connected to the second electrode CE2 of the fourth touch group TG4 may be fourth pixels, but are not necessarily limited thereto. Accordingly, the pixel driver PD may supply a voltage to the first common electrode and the second common electrode. The pixel driver PD may supply a common voltage to the first common electrode and the second common electrode to display an image or may supply a touch driving signal to the first common electrode and the second common electrode to sense touch.

Further, the second electrode CE2 may function as an electrode that is used for touch sensing. When the second electrode CE2 functions as a touch electrode during the touch sensing periods T1, T2, T3, and T4, touch information sensed in the pixel drivers PD electrically connected through the plurality of contact electrodes CCE, for example, can be calculated.

The plurality of second electrodes CE2 may be made of a transparent conductive material, but the embodiments of the present disclosure are not limited thereto. The plurality of second electrodes CE2 may be made of a transparent conductive material so that light emitted from the light emitting elements ED can be directed toward upper sides of the second electrodes CE2. For example, the second electrode CE2 may be made of a transparent conductive material such as indium tin oxide (ITO), indium zinc oxide (IZO), indium gallium oxide (IGO) or indium gallium zinc oxide (IGZO), but the embodiments of the present disclosure are not limited thereto.

The plurality of contact electrodes CCE may be disposed on the substrate 110. For example, the plurality of contact electrodes CCE may be disposed apart from the plurality of banks BNK and the plurality of signal wirings TL. Each of the plurality of second electrodes CE2 may overlap at least one contact electrode CCE. For example, one second electrode CE2 may overlap the plurality of contact electrodes CCE.

For example, the plurality of contact electrodes CCE may be electrically connected to the plurality of second electrodes CE2. The plurality of contact electrodes CCE may be disposed between the substrate 110 and the plurality of second electrodes CE2 to transmit the cathode voltage from the pixel driver PD to the second electrodes CE2. When the second electrodes CE2 function as touch electrodes, the sensed touch information may be transmitted to the pixel driver PD through the plurality of contact electrodes CCE.

For example, one pixel driver PD may be electrically connected to the second electrodes CE2 disposed in the adjacent touch groups TG1 and TG3 that are included in the same touch unit through the plurality of contact electrodes CCE. The pixel driver PD may be disposed in an overlapping manner below two touch groups adjacent in the column direction among the touch groups within the same touch unit. For example, the pixel driver PD may be disposed in an overlapping manner between the first touch group TG1 and the third touch group TG3 within a touch unit, but the embodiments of the present disclosure are not limited thereto. For example, another adjacent pixel driver PD may be disposed in an overlapping manner between the second touch group TG2 and the fourth touch group TG4 within a touch unit.

For example, when a μLED is used as the light emitting element ED, a plurality of μLED may be formed on a wafer and the μLED may be transferred to the substrate 110 of the display device 1000 to manufacture the display device 1000. Various defects may occur during the process of transferring the plurality of light emitting elements ED having a micro size from the wafer to the substrate 110. For example, in some of the sub-pixels, a non-transfer defect in which the light emitting element ED is not transferred may occur, and in other sub-pixels, a defect in which the light emitting element ED is transferred out of its correct position due to an alignment error may occur. Further, even if the transfer process is performed normally, the transferred light emitting element ED itself may be defective. Therefore, a plurality of light emitting elements ED of the same type may be transferred to one sub-pixel in consideration of defects during a process of transferring the plurality of light emitting elements ED. A lighting test of the plurality of light emitting elements ED may be performed, and only one light emitting element ED that is ultimately determined to be normal may be used.

For example, the (1-1)-th light emitting element 130a and the (1-2)-th light emitting element 130b may be transferred together to one pixel PX, and whether or not the (1-1)-th light emitting element 130a and the (1-2)-th light emitting element 130b are defective may be inspected. When both the (1-1)-th light emitting element 130a and the (1-2)-th light emitting element 130b are determined to be normal, the (1-1)-th light emitting element 130a may be used and the (1-2)-th light emitting element 130b may not be used. In another example, when the (1-2)-th light emitting element 130b among the (1-1)-th light emitting elements 130a and the (1-2)-th light emitting elements 130b is determined to be normal, the (1-1)-th light emitting element 130a may not be used, and the (1-2)-th light emitting element 130b may be used. Accordingly, even when the plurality of light emitting elements ED of the same type are transferred to one pixel PX, only one of the light emitting elements ED may be used ultimately.

Accordingly, one light emitting element ED in one pair may be a main (or primary) light emitting element ED and the other may be a redundant light emitting element ED. The redundant light emitting element ED may be a redundant light emitting element ED that is transferred in preparation for a defect of the main light emitting element ED. When the main light emitting element ED is defective, the redundant light emitting element ED may be used as a replacement. Thus, the main light emitting element ED and the redundant light emitting element ED are together transferred to one pixel PX, thereby minimizing or reducing the deterioration of display quality due to a defect of the main light emitting element ED and the redundant light emitting element ED.

For example, the (1-1)-th light emitting element 130a, the (2-1)-th light emitting element 140a, and the (3-1)-th light emitting element 150a transferred to one pixel PX may be used as main light emitting elements ED, and the (1-2)-th light emitting element 130b, the (2-2)-th light emitting element 140b, and the (3-2)-th light emitting element 150b may be used as the redundant light emitting elements ED. Embodiments of the present disclosure are not limited thereto.

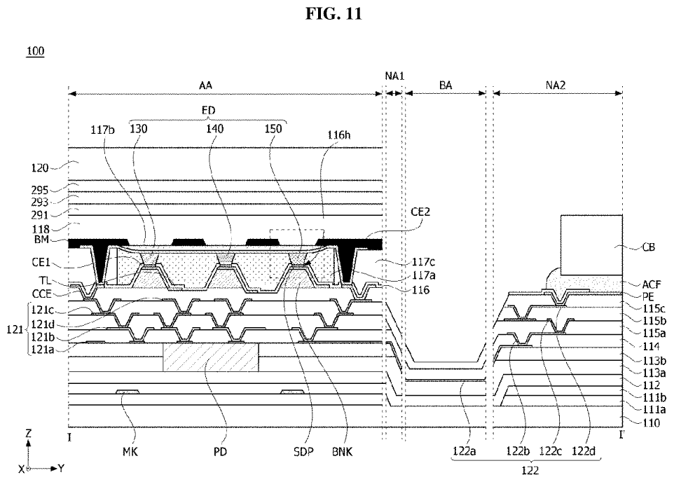

FIG. 11 is a cross-sectional view taken along line I-I″ of FIG. 3 according to one embodiment. FIG. 12 is a cross-sectional view illustrating a sub-pixel including a light emitting element disposed in the display area according to one embodiment.

Referring to FIG. 11, a first buffer layer 111a and a second buffer layer 111b may be disposed in an area of the substrate 110 other than the bending area BA.

The first buffer layer 111a and the second buffer layer 111b may be disposed in the display area AA, the first non-display area NA1, and the second non-display area NA2. The first buffer layer 111a and the second buffer layer 111b can reduce the intrusion of foreign matters such as moisture, oxygen, hydrogen, or impurities through the substrate 110. The first buffer layer 111a and the second buffer layer 111b may be made of an inorganic insulating material. For example, the first buffer layer 111a and the second buffer layer 111b may be configured of a single layer or a multi-layer of silicon oxide (SiOx), silicon nitride (SiNx) or silicon oxynitride (SiOxNy), but the embodiments of the present disclosure are not limited thereto.

For example, a portion of the first buffer layer 111a and the second buffer layer 111b on the bending area BA may be removed. An upper surface of the substrate 110 located in the bending area BA may be exposed from the first buffer layer 111a and the second buffer layer 111b. The first buffer layer 111a and the second buffer layer 111b made of an inorganic insulating material are removed in the bending area BA so that cracks in the first buffer layer 111a and the second buffer layer 111b that may occur during bending can be minimized or at least reduced.

A plurality of alignment keys MK may be disposed between the first buffer layer 111a and the second buffer layer 11b. The plurality of alignment keys MK may be configured to identify positions of the pixel drivers PD during a process of manufacturing the display device 1000. For example, the plurality of alignment keys MK may be configured to align the positions of the pixel drivers PD transferred onto an adhesive layer 112. In another example, the plurality of alignment keys MK may be omitted.

The adhesive layer 112 may be disposed on the second buffer layer 111b. The adhesive layer 112 may be disposed in the display area AA, the first non-display area NA1, the bending area BA, and the second non-display area NA2. In another example, at least a portion of the adhesive layer 112 may be removed in the non-display area NA including the bending area BA. For example, the adhesive layer 112 may be made of any one of an optically clear adhesive (OCA), an optically clear resin (OCR), a pressure sensitive adhesive (PSA), a silicone resin, an adhesive polymer, an epoxy resin, a UV-curable resin, a polyimide series, an acrylate series, a urethane series, and polydimethylsiloxane (PDMS), but the embodiments of the present disclosure are not limited thereto.

The pixel driver PD may be disposed on the adhesive layer 112 in the display area AA. The pixel driver PD may be mounted on the adhesive layer 112 by a transfer process, but the embodiments of the present disclosure are not limited thereto.

A first protective layer 113a and a second protective layer 113b may be disposed on the adhesive layer 112 and the pixel driver PD. The first protective layer 113a and the second protective layer 113b may be disposed to surround a side surface of the pixel driver PD, but the embodiments of the present disclosure are not limited thereto. For example, the second protective layer 113b may be disposed to cover at least a portion of an upper surface of the pixel driver PD. For example, at least one of the first protective layer 113a and the second protective layer 113b disposed in the bending area BA may be omitted. For example, the first protective layer 113a may be disposed in the entire display area AA and the entire non-display area NA, and the second protective layer 113b may be disposed partially in the display area AA, the first non-display area NA1, and the second non-display area NA2. For example, a portion of the second protective layer 113b in the bending area BA may be removed. However, the embodiments of the present disclosure are not limited thereto.

The first protective layer 113a and the second protective layer 113b may be made of an organic insulating material, but the embodiments of the present disclosure are not limited thereto. For example, the first protective layer 113a and the second protective layer 113b may be made of an acrylic resin, a phenolic resin, an unsaturated polyester resin, a polyamide resin, a benzocyclobutene, a polyphenylene resin, a polyphenylene sulfide resin, a photo resist, a polyimide (PI), a photo acryl-based material, or the like, but the embodiments of the present disclosure are not limited thereto. For example, the first protective layer 113a and the second protective layer 113b may be an overcoating layer or an insulating layer, but the embodiments of the present disclosure are not limited thereto. The first protective layer 113a and the second protective layer 113b may be made of the same or different materials.

According to the present disclosure, a plurality of first connection wirings 121 may be disposed on the second protective layer 113b in the display area AA. The plurality of first connection wirings 121 may be wirings for electrically connecting the pixel driver PD to other components. For example, the pixel driver PD may be electrically connected to the plurality of signal wirings TL, the plurality of contact electrodes CCE, and the like through the plurality of first connection wirings 121. For example, the plurality of first connection wirings 121 may include a (1-1)-th connection wiring 121a, a (1-2)-th connection wiring 121b, a (1-3)-th connection wiring 121c, and a (1-4)-th connection wiring 121d, but the embodiments of the present disclosure are not limited thereto.

For example, the plurality of (1-1)-th connection wirings 121a may be disposed on the second protective layer 113b. The plurality of (1-1)-th connection wirings 121a may be electrically connected to the pixel driver PD. The plurality of (1-1)-th connection wirings 121a may transmit the voltage and/or other signals output from the pixel driver PD to the first electrode CE1 or the second electrode CE2.

For example, a third protective layer 114 may be disposed on the second protective layer 113b. The third protective layer 114 may be disposed in the entire display area AA and the entire non-display area NA. In the bending area BA, the third protective layer 114 may cover a side surface of the second protective layer 113b and an upper surface of the first protective layer 113a. The third protective layer 114 may be made of an organic insulating material. For example, the third protective layer 114 may be made of an acrylic resin, a phenolic resin, an unsaturated polyester resin, a polyamide resin, a benzocyclobutene, a polyphenylene resin, a polyphenylene sulfide resin, a photo resist, a polyimide (PI), a photo acryl-based material, or the like, but the embodiments of the present disclosure are not limited thereto. For example, the first protective layer 113a, the second protective layer 113b, and the third protective layer 114 may be made of the same material, but the embodiments of the present disclosure are not limited thereto. Alternatively, the third protective layer 114 may be made of a material different from the first protective layer 113a and the second protective layer 113b.

A plurality of (1-2)-th connection wirings 121b may be disposed on the third protective layer 114. The plurality of (1-2)-th connection wirings 121b may be indirectly connected to or directly connected to the pixel driver PD. For example, a portion of the (1-2)-th connection wiring 121b may be directly connected to the pixel driver PD through a contact hole of the third protective layer 114. Alternatively, a portion of the (1-2)-th connection wiring 121b may be connected to the pixel driver PD through a contact hole of the third protective layer 114 and the (1-1)-th connection wirings 121a. Another portion of the (1-2)-th connection wiring 121b may be electrically connected to the (1-1)-th connection wiring 121a through the contact hole of the third protective layer 114. However, the embodiments of the present disclosure are not limited thereto. The voltage and/or other signals output from the pixel driver PD may be transmitted to the first electrode CE1 or the second electrode CE2 through the plurality of (1-2)-th connection wirings 121b and other connection wirings.

A first insulating layer 115a may be disposed on the plurality of (1-2)-th connection wirings 121b. The first insulating layer 115a may be disposed in the entire display area AA and the entire non-display area NA, but the embodiments of the present disclosure are not limited thereto. Alternatively, the first insulating layer 115a may be disposed partially in the display area AA, the first non-display area NA1 and the second non-display area NA2. For example, a portion of the first insulating layer 115a in the bending area BA may be removed. The first insulating layer 115a may be made of an organic insulating material, but the embodiments of the present disclosure are not limited thereto. For example, the first insulating layer 115a may be made of an acrylic resin, a phenolic resin, an unsaturated polyester resin, a polyamide resin, a benzocyclobutene, a polyphenylene resin, a polyphenylene sulfide resin, a photo resist, a polyimide (PI), a photo acryl-based material, or the like, but the embodiments of the present disclosure are not limited thereto.

A plurality of (1-3)-th connection wirings 121c may be disposed on the first insulating layer 115a. The plurality of (1-3)-th connection wirings 121c may be electrically connected to a plurality of (1-2)-th connection wirings 121b. For example, the (1-3)-th connection wirings 121c may be electrically connected to the (1-2)-th connection wirings 121b through contact holes of the first insulating layer 115a, and in turn electrically connected to the (1-1)-th connection wirings 121a through contact holes of the third insulating layer 114.

A second insulating layer 115b may be disposed on the plurality of (1-3)-th connection wirings 121c. The second insulating layer 115b may be disposed in an area other than the bending area BA, but the embodiments of the present disclosure are not limited thereto. The second insulating layer 115b may be disposed in the display area AA, the first non-display area NA1, and the second non-display area NA2, but the embodiments of the present disclosure are not limited thereto. For example, a portion of the second insulating layer 115b disposed in the bending area BA may be removed. The second insulating layer 115b may be made of an organic insulating material, but the embodiments of the present disclosure are not limited thereto. For example, the second insulating layer 115b may be made of an acrylic resin, a phenolic resin, an unsaturated polyester resin, a polyamide resin, a benzocyclobutene, a polyphenylene resin, a polyphenylene sulfide resin, a photo resist, a polyimide (PI), a photo acryl-based material, or the like, but the embodiments of the present disclosure are not limited thereto.

A plurality of (1-4)-th connection wirings 121d may be disposed on the second insulating layer 115b. The plurality of (1-4)-th connection wirings 121d may be electrically connected to the plurality of (1-3)-th connection wirings 121c. For example, the (1-4)-th connection wirings 121d may be electrically connected to the (1-3)-th connection wirings 121c through contact holes of the second insulating layer 115b, in turn electrically connected to the (1-2)-th connection wirings 121b through contact holes of the first insulating layer 115a, and in turn electrically connected to the (1-1)-th connection wirings 121a through contact holes of the third insulating layer 114.

According to the present disclosure, a plurality of second connection wirings 122 may be disposed on the second protective layer 113b in the non-display area NA. The plurality of second connection wirings 122 may be wirings for transmitting signals, which are transmitted from the flexible circuit boards (or flexible films) CB and/or the printed circuit boards 160 (see FIG. 1) to the pad parts PAD, to the pixel drivers PD in the display area AA. For example, the plurality of second connection wirings 122 may be electrically connected to the plurality of pad electrodes PE to receive signals from the flexible circuit boards (or flexible films) CB and/or the printed circuit boards.

For example, the plurality of second connection wirings 122 may extend from the pad part PAD toward the display area AA to transmit the signals to the wirings in the display area AA. In this case, the plurality of second connection wirings 122 may function as the link wirings LL. The plurality of second connection wirings 122 may include a (2-1)-th connection wiring 122a, a (2-2)-th connection wiring 122b, a (2-3)-th connection wiring 122c, and a (2-4)-th connection wiring 122d. The (2-1)-th connection wiring 122a in the first non-display area NA1 may be electrically connected or coupled to the (1-1)-th connection wiring 122a in the display area AA.

A plurality of (2-1)-th connection wirings 122a may be disposed on the second protective layer 113b. The plurality of (2-1)-th connection wirings 122a may extend from the second non-display area NA2 to the bending area BA and the first non-display area NA1.

The plurality of (2-1)-th connection wirings 122a may be electrically connected to the plurality of (1-2)-th connection wirings 121b in the display area AA. The plurality of (2-1)-th connection wirings 122a may transmit the signals, which are transmitted from the flexible circuit boards (or flexible films) CB and/or the printed circuit boards to the pad parts PAD, to the pixel drivers PD in the display area AA.

A plurality of (2-2)-th connection wirings 122b may be disposed on the third protective layer 114. The plurality of (2-2)-th connection wirings 122b may be disposed in the second non-display area NA2. The (2-2)-th connection wirings 122b may be electrically connected to the (2-1)-th connection wirings 122a through contact holes of the third protective layer 114. Therefore, the signals from the flexible circuit boards (or flexible films) CB and/or the printed circuit boards may be transmitted to the (2-1)-th connection wirings 122a through the (2-2)-th connection wirings 122b.

The (2-3)-th connection wiring 122c may be disposed on the first insulating layer 115a. The (2-3)-th connection wiring 122c may be disposed in the second non-display area NA2. The (2-3)-th connection wiring 122c may be electrically connected to the (2-2)-th connection wiring 122b through the contact hole of the first insulating layer 115a, and in turn electrically connected to the (2-1)-th connection wirings 122a through contact holes of the third protective layer 114. Therefore, the signal from the flexible circuit board (or flexible film) CB and/or the printed circuit board may be transmitted to the (2-1)-th connection wiring 122a through the (2-3)-th connection wiring 122c and the (2-2)-th connection wiring 122b.

The (2-4)-th connection wiring 122d may be disposed on the second insulating layer 115b. The (2-4)-th connection wiring 122d may be disposed in the second non-display area NA2. The (2-4)-th connection wiring 122d may be electrically connected to the (2-3)-th connection wiring 122c through the contact hole of the second insulating layer 115b, in turn electrically connected to the (2-2)-th connection wirings 122b through contact holes of the first insulating layer 115a, and in turn electrically connected to the (2-1)-th connection wirings 122a through contact holes of the third protective layer 114. Accordingly, the signal from the flexible film CB and/or the printed circuit board may be transmitted to the (2-1)-th connection wiring 122a through the (2-4)-th connection wiring 122d, the (2-3)-th connection wiring 122c, and the (2-2)-th connection wiring 122b.

The plurality of first connection wirings 121 and the plurality of second connection wirings 122 may be formed of a conductive material with excellent flexibility or any one of various conductive materials used in the display area AA. For example, the second connection wiring 122 partially disposed in the bending area BA may be made of a conductive material having excellent flexibility such as gold (Au), silver (Ag), Copper (Cu) or aluminum (Al), but the embodiments of the present disclosure are not limited thereto. In another example, the plurality of first connection wirings 121 and the plurality of second connection wirings 122 may be made of, for example, molybdenum (Mo), chromium (Cr), titanium (Ti), gold (Au), aluminum (Al), nickel (Ni), neodymium (Nd), copper (Cu), an alloy of silver (Ag) and magnesium (Mg), or an alloy thereof, but the embodiments of the present disclosure are not limited thereto. The plurality of first connection wirings 121 and the plurality of second connection wirings 122 may be formed of the same or different materials.

A third insulating layer 115c may be disposed on the plurality of first connection wirings 121 and the plurality of second connection wirings 122. The third insulating layer 115c may be disposed in an area other than the bending area BA, but the embodiments of the present disclosure are not limited thereto. The third insulating layer 115c may be disposed in the display area AA, the first non-display area NA1, and the second non-display area NA2. A portion of the third insulating layer 115c in the bending area BA may be removed. The third insulating layer 115c may be made of an organic insulating material, but the embodiments of the present disclosure are not limited thereto. For example, the third insulating layer 115c may be made of an acrylic resin, a phenolic resin, an unsaturated polyester resin, a polyamide resin, a benzocyclobutene, a polyphenylene resin, a polyphenylene sulfide resin, a photo resist, a polyimide (PI), a photo acryl-based material, or the like, but the embodiments of the present disclosure are not limited thereto.

The plurality of banks BNK may be disposed on the third insulating layer 115c in the display area AA. The plurality of banks BNK may be disposed to overlap the plurality of sub-pixels. One or more light emitting elements ED of the same or different types may be disposed on each of the plurality of banks BNK.

The plurality of signal wirings TL may be disposed on the third insulating layer 115c in the display area AA. The plurality of signal wirings TL may be disposed in an area between the plurality of banks BNK. For example, the plurality of signal wirings TL may be disposed adjacent to one of the plurality of banks BNK.

The plurality of contact electrodes CCE may be disposed on the third insulating layer 115c in the display area AA. The plurality of contact electrodes CCE may supply the cathode voltage from the pixel driver PD to the second electrode CE2.

The first electrode CE1 may be disposed on the bank BNK. For example, the first electrode CE1 may be disposed to extend from an adjacent signal wiring TL toward an upper side of the bank BNK. The first electrode CE1 may be disposed on an upper surface of the bank BNK and a side surface of the bank BNK. For example, the first electrode CE1 may be disposed to extend from the signal wiring TL on an upper surface of the third insulating layer 115c to the side surface of the bank BNK and the upper surface of the bank BNK.

Referring to FIG. 12, the first electrode CE1 may be configured of a plurality of conductive layers. For example, the first electrode CE1 may include a first conductive layer CE1a, a second conductive layer CE1b, a third conductive layer CE1c, and a fourth conductive layer CE1d, but the embodiments of the present disclosure are not limited thereto.

The first conductive layer CE1a may be disposed on the bank BNK. The second conductive layer CE1b may be disposed on the first conductive layer CE1a. The third conductive layer CE1c may be disposed on the second conductive layer CE1b. The fourth conductive layer CE1d may be disposed on the third conductive layer CE1c. For example, each of the first conductive layer CE1a, the second conductive layer CE1b, the third conductive layer CE1c, and the fourth conductive layer CE1d may be made of titanium (Ti), molybdenum (Mo), aluminum (Al), or an alloy of titanium (Ti) and indium tin oxide (ITO), or an alloy thereof, but the embodiments of the present disclosure are not limited thereto.

According to the present disclosure, some conductive layers having good reflection efficiency among the plurality of conductive layers constituting the first electrode CE1 may be configured as a reflector and/or an alignment key for alignment of the light emitting elements ED. For example, the second conductive layer CE1b among the plurality of conductive layers of the first electrode CE1 may include a reflective material. For example, the second conductive layer CE1b may include aluminum (Al), silver (Ag), gold (Au), magnesium (Mg), but the embodiments of the present disclosure are not limited thereto. Thus, the second conductive layer CE1b may be configured as a reflector. Further, the second conductive layer CE1b can be easily identified in a manufacturing process due to the high reflection efficiency of the second conductive layer CE1b, and therefore positions or transfer positions of the light emitting elements ED may be aligned with the second conductive layer CE1b as a reference.

For example, in order to configure the second conductive layer CE1b as a reflector, the third conductive layer CE1c and the fourth conductive layer CE1d covering the second conductive layer CE1b may be partially removed or etched. For example, a portion of the third conductive layer CE1c and the fourth conductive layer CE1d disposed on the bank BNK may be removed or etched to expose an upper surface of the second conductive layer CE1b. For example, a central portion and a border portion (or edge portion) where a solder pattern SDP is disposed in the third conductive layer CE1c and the fourth conductive layer CE1d may be left, and the remaining portion may be removed. For example, a border portion (or edge portion) of each of the third conductive layer CE1c made of e.g. titanium (Ti) and the fourth conductive layer CE1d made of e.g. indium tin oxide (ITO) may not be etched. This can prevent or at least reduce the other conductive layers of the first electrode CE1 from being corroded by a tetramethylammonium hydroxide (TMAH) solution used in a mask process for the first electrode CE1.

According to the present disclosure, the first conductive layer CE1a and the third conductive layer CE1c may include titanium (Ti) or molybdenum (Mo). The second conductive layer CE1b may for example include aluminum (Al), silver (Ag), gold (Au), magnesium (Mg) etc. The fourth conductive layer CE1d may include a transparent conductive oxide layer such as indium tin oxide (ITO), indium gallium oxide (IGO), indium zinc oxide (IZO) or indium gallium zinc oxide (IGZO) having good adhesion to the solder pattern SDP and having corrosion resistance and acid resistance. However, the embodiments of the present disclosure are not limited thereto.

The first conductive layer CE1a, the second conductive layer CE1b, the third conductive layer CE1c, and the fourth conductive layer CE1d may be sequentially deposited and then patterned by performing a photolithography process and an etching process, but the embodiments of the present disclosure are not limited thereto.

According to the present disclosure, the signal wiring TL, the contact electrode CCE, and the pad electrode PE disposed on the same layer as the first electrode CE1 may be configured as a multilayer of conductive materials, but the embodiments of the present disclosure are not limited thereto. For example, the signal wiring TL, the contact electrode CCE, and the pad electrode PE may be configured as a multilayer of indium tin oxide (ITO))/titanium (Ti)/aluminum (Al))/titanium (Ti), indium tin oxide (ITO)/aluminum (Al)/indium tin oxide (ITO), ITO/APC/ITO, etc., but the embodiments of the present disclosure are not limited thereto.

According to the present disclosure, the solder pattern SDP may be disposed on the first electrode CE1 in each of the plurality of sub-pixels such that the solder pattern SDP is between the first electrode CE1 and the first semiconductor layer 131. The solder pattern SDP may bond the light emitting element ED to the first electrode CE1. The first electrode CE1 and the light emitting element ED may be electrically connected through eutectic bonding using the solder pattern SDP, but the embodiments of the present disclosure are not limited thereto. For example, when the solder pattern SDP is made of e.g. indium (In) and the anode electrode 134 of the light emitting element ED is made of e.g. gold (Au), the solder pattern SDP and the anode electrode 134 may be bonded by applying heat and pressure in the transfer process for the light emitting element ED. Through eutectic bonding, the light emitting element ED may be bonded to the solder pattern SDP and the first electrode CE1 without a separate adhesive. For example, the solder pattern SDP may be made of indium (In), tin (Sn), or an alloy thereof, but the embodiments of the present disclosure are not limited thereto. For example, the solder pattern SDP may be a bonding pad, a binding pad, or the like, but the embodiments of the present disclosure are not limited thereto.

According to the present disclosure, a passivation layer 116 may be disposed on the plurality of signal wirings TL, the plurality of first electrodes CE1, the plurality of contact electrodes CCE, and the third insulating layer 115c. For example, the passivation layer 116 may be disposed in the display area AA, the first non-display area NA1, and the second non-display area NA2. A portion of the passivation layer 116 disposed in the bending area BA may be removed. A portion of the passivation layer 116 covering the plurality of pad electrodes PE in the second non-display area NA2 may be removed. Since the passivation layer 116 is disposed to cover an area other than the bending area BA and an area where the plurality of pad electrodes PE and solder patterns SDP are disposed, it is possible to reduce the intrusion of foreign matters such as moisture or impurities into the light emitting elements ED. For example, the passivation layer 116 may be configured as a single layer or a multi-layer of silicon oxide (SiOx), silicon nitride (SiNx) or silicon oxynitride (SiOxNy), but the embodiments of the present disclosure are not limited thereto. For example, the passivation layer 116 may be a protective layer or an insulating layer, but the embodiments of the present disclosure are not limited thereto. For example, the passivation layer 116 may include an opening 116h that exposes the solder pattern SDP.

The light emitting element ED may be disposed on the solder pattern SDP in each of the plurality of sub-pixels. For example, the first light emitting element 130 may be disposed in the first sub-pixel SP1, the second light emitting element 140 may be disposed in the second sub-pixel SP2and the third light emitting element 150 may be disposed in the third sub-pixel SP3.

The light emitting element ED may be formed on a silicon wafer by using a method such as metal organic chemical vapor deposition (MOCVD), chemical vapor deposition (CVD), plasma-enhanced chemical vapor deposition (PECVD), molecular beam epitaxy (MBE), hydride vapor phase epitaxy (HVPE), Laser assisted Deposition (LCVD), atomic layer deposition (ALD), thermal evaporation or sputtering, but the embodiments of the present disclosure are not limited thereto.

The first light emitting element 130 may include an anode electrode 134, a first semiconductor layer 131, an active layer 132, a second semiconductor layer 133, a cathode electrode 135, and a sealing film 136, but the embodiments of the present disclosure are not limited thereto. For example, the sealing film 136 may not be included in the first light emitting element 130.

The first semiconductor layer 131 may be disposed on the solder pattern SDP. The second semiconductor layer 133 may be disposed on the first semiconductor layer 131.

For example, one of the first semiconductor layer 131 and the second semiconductor layer 133 may be implemented as a compound semiconductor of group III-V, group II-VI, or the like, and may be doped with an impurity (or dopant). For example, one of the first semiconductor layer 131 and the second semiconductor layer 133 may be a semiconductor layer doped with an n-type impurity, and the other may be a semiconductor layer doped with a p-type impurity, but the embodiments of the present disclosure are not limited thereto. For example, at least one of the first semiconductor layer 131 and the second semiconductor layer 133 may be a layer obtained by doping a material such as gallium nitride (GaN), gallium phosphide (GaP), gallium arsenide phosphide (GaAsP), indium gallium nitride (InGaN), aluminum gallium indium phosphide (AlGaInP), indium aluminum phosphide (InAlP), aluminum gallium nitride (AlGaN), aluminum indium gallium nitride (AlInGaN), aluminum indium nitride (AlInN), aluminum indium gallium nitride (AlInGaN), aluminum gallium nitride (AlGaN), aluminum gallium arsenide (AlGaAs), or gallium arsenide (GaAs) with an n-type or p-type impurity, but the embodiments of the present disclosure are not limited thereto. For example, the n-type impurity may be phosphide (P), antimony (Sb), arsenide (As), silicon (Si), germanium (Ge), selenium (Se), carbon (C), tellurium (Te), tin (Sn), or the like, but the embodiments of the present disclosure are not limited thereto. For example, the p-type impurity may be boron (B), aluminum (Al), gallium (Ga), magnesium (Mg), zinc (Zn), calcium (Ca), strontium (Sr), barium (Ba), beryllium (Be), or the like, but the embodiments of the present disclosure are not limited thereto.

For example, each of the first semiconductor layer 131 and the second semiconductor layer 133 may be a nitride semiconductor including an n-type impurity and a nitride semiconductor including a p-type impurity, but the embodiments of the present disclosure are not limited thereto. For example, the first semiconductor layer 131 may be a nitride semiconductor including a p-type impurity, and the second semiconductor layer 133 may be a nitride semiconductor including an n-type impurity, but the embodiments of the present disclosure are not limited thereto.

The active layer 132 may be disposed between the first semiconductor layer 131 and the second semiconductor layer 133. The active layer 132 may receive holes and electrons from the first semiconductor layer 131 and the second semiconductor layer 133 to emit light. For example, the active layer 132 may be configured in one of a single well structure, a multi-well structure, a single quantum well structure, a multi-quantum well (MQW) structure, a quantum dot structure, and a quantum wire structure, but the embodiments of the present disclosure are not limited thereto. For example, the active layer 132 may be made of indium phosphide (InP), gallium arsenide (GaAs), aluminum gallium arsenide (AlGaAs), indium gallium nitride (InGaN), gallium nitride (GaN), or the like, but the embodiments of the present disclosure are not limited thereto.

In another example, the active layer 132 may include a multi-quantum well (MQW) structure having a well layer and a barrier layer having a higher band gap than the well layer. For example, the active layer 132 may include the well layer made of e.g. InGaN and the barrier layer made of e.g. AlGaN, but the embodiments of the present disclosure are not limited thereto.

The anode electrode 134 may be disposed between the first semiconductor layer 131 and the solder pattern SDP. For example, the anode electrode 134 may electrically connect the first semiconductor layer 131 and the first electrode CE1. The anode voltage output from the pixel driver PD may be applied to the first semiconductor layer 131 through the signal wiring TL, the first electrode CE1, and the anode electrode 134. For example, the anode electrode 134 may be made of a conductive material capable of being eutectically bonded to the solder pattern SDP, but the embodiments of the present disclosure are not limited thereto. For example, the anode electrode 134 may be made of gold (Au), tin (Sn), tungsten (W), silicon (Si), silver (Ag), titanium (Ti), iridium (Ir), chromium (Cr), indium (In), zinc (Zn), lead (Pb), nickel (Ni), platinum (Pt), copper (Cu), or an alloy thereof, but the embodiments of the present disclosure are not limited thereto.

The cathode electrode 135 may be disposed on the second semiconductor layer 133. For example, the cathode electrode 135 may electrically connect the second semiconductor layer 133 and the second electrode CE2. The cathode voltage output from the pixel driver PD may be applied to the second semiconductor layer 133 through the contact electrode CCE, the second electrode CE2, and the cathode electrode 135. The cathode electrode 135 may be made of a transparent conductive material so that the light emitted from the light emitting element ED can be directed to the upper side of the light emitting element ED, but the embodiments of the present disclosure are not limited thereto. For example, the cathode electrode 135 may be made of a material such as indium tin oxide (ITO), indium zinc oxide (IZO), indium gallium oxide (IGO) or indium gallium zinc oxide (IGZO), but the embodiments of the present disclosure are not limited thereto.

The sealing film 136 may be disposed on at least a portion of the first semiconductor layer 131, the active layer 132, the second semiconductor layer 133, the anode electrode 134, and the cathode electrode 135. For example, the sealing film 136 may surround the at least a portion of the first semiconductor layer 131, the active layer 132, the second semiconductor layer 133, the anode electrode 134, and the cathode electrode 135.

For example, the sealing film 136 can protect the first semiconductor layer 131, the active layer 132, and the second semiconductor layer 133. For example, the sealing film 136 may be disposed on a side surface of the first semiconductor layer 131, a side surface of the active layer 132, and a side surface of the second semiconductor layer 133.

For example, the sealing film 136 may be disposed on at least a portion of the anode electrode 134 and the cathode electrode 135, for example, an edge portion (or one side) of the anode electrode 134 and an edge portion (or one side) of the cathode electrode 135. At least a portion of the anode electrode 134 may be exposed from the sealing film 136 so that the anode electrode 134 and the solder pattern SDP can be connected. For example, at least a portion of the cathode electrode 135 may be exposed from the sealing film 136 so that the cathode electrode 135 and the second electrode CE2 can be connected. For example, the sealing film 136 may be made of an insulating material such as silicon nitride (SiNx), silicon oxide (SiOx) or silicon oxynitride (SiOxNy), but the embodiments of the present disclosure are not limited thereto.

In another example, the sealing film 136 may have a structure in which a reflective material is dispersed in a resin layer, but the embodiments of the present disclosure are not limited thereto. For example, the sealing film 136 may be manufactured as a reflector having various structures, but the embodiments of the present disclosure are not limited thereto. Light emitted from the active layer 132 may be reflected upward by the sealing film 136, thereby improving light extraction efficiency. For example, the sealing film 136 may be a reflective layer, but the embodiments of the present disclosure are not limited thereto.

According to the present disclosure, the light emitting element ED has been described as having a vertical structure, but the embodiments of the present disclosure are not limited thereto. For example, the light emitting element ED may have a lateral structure or a flip chip structure.

The first light emitting element 130 has been described with reference to FIG. 12, and the second light emitting element 140 and the third light emitting element 150 may have substantially the same structure as the first light emitting element 130. For example, the second light emitting element 140 and the third light emitting element 150 may include substantially the same components as the first semiconductor layer 131, the active layer 132, the second semiconductor layer 133, the anode electrode 134, the cathode electrode 135, and the sealing film 136 of the first light emitting element 130.

A first optical layer 117a surrounding the plurality of light emitting elements ED may be disposed in the display area AA. For example, the first optical layer 117a may be disposed to cover the plurality of light emitting elements ED and the banks BNK in areas of the plurality of sub-pixels. For example, the first optical layer 117a may cover the banks BNK, a portion of the passivation layer 116, and an area between the plurality of light emitting elements ED. The first optical layer 117a may be disposed between the plurality of light emitting elements ED and between the plurality of banks BNK included in one pixel PX or cover such areas. For example, the first optical layers 117a may extend in a first direction X and may be disposed apart from each other in a second direction Y For example, the first optical layer 117a may be disposed to surround the sides of the light emitting element ED and the bank BNK between the passivation layer 116 and the second electrode CE2, but the embodiments of the present disclosure are not limited thereto. For example, the first optical layer 117a may be a diffusion layer or a sidewall diffusion layer, but the embodiments of the present disclosure are not limited thereto.

The first optical layer 117a may include an organic insulating material in which fine particles are dispersed, but the embodiments of the present disclosure are not limited thereto. For example, the first optical layer 117a may be made of siloxane in which fine metal particles such as titanium dioxide (TiO2) particles are dispersed, but the embodiments of the present disclosure are not limited thereto. Light from the plurality of light emitting elements ED may be scattered by the fine particles dispersed in the first optical layer 117a and emitted to the outside of the display device 1000. Accordingly, the first optical layer 117a can improve the extraction efficiency of light emitted from the plurality of light emitting elements ED.

For example, the first optical layer 117a may be disposed on each of the plurality of pixels PX or may be disposed on some of the pixels PX disposed in the same row, but the embodiments of the present disclosure are not limited thereto. For example, the first optical layer 117a may be disposed on each of the plurality of pixels PX, or one first optical layer 117a may be shared by the plurality of pixels PX. In another example, each of the plurality of sub-pixels may separately include the first optical layer 117a, but the embodiments of the present disclosure are not limited thereto.

According to the present disclosure, the third optical layer 117c may be disposed on the passivation layer 116 in the display area AA. For example, the third optical layer 117c may be disposed to surround the first optical layer 117a. For example, the third optical layer 117c may be in contact with a side surface of the first optical layer 117a. For example, the third optical layer 117c may be disposed in an area between the plurality of pixels PX. However, the embodiments of the present disclosure are not limited thereto. For example, the third optical layer 117c may be a diffusion layer, a diffusion layer window, a window diffusion layer, or the like, but the embodiments of the present disclosure are not limited thereto.

The third optical layer 117c may be made of an organic insulating material, but the embodiments of the present disclosure are not limited thereto. The third optical layer 117c may be made of the same or different materials as the first optical layer 117a, but the embodiments of the present disclosure are not limited thereto. For example, the first optical layer 117a may include fine particles, and the third optical layer 117c may not include fine particles. For example, the third optical layer 117c may be made of a siloxane, but the embodiments of the present disclosure are not limited thereto.

For example, a thickness of the first optical layer 117a may be smaller than a thickness of the third optical layer 117c, but the embodiments of the present disclosure are not limited thereto. Accordingly, an area where the first optical layer 117a is disposed may include a concave portion that is sunk inward from an upper surface of the third optical layer 117c in a plan view.

According to the present disclosure, the second electrode CE2 may be disposed on the first optical layer 117a and the third optical layer 117c. For example, the second electrode CE2 may be electrically connected to the plurality of contact electrodes CCE through contact holes of the third optical layer 117c. For example, the second electrode CE2 may be disposed on the plurality of light emitting elements ED. For example, the second electrode CE2 may include a transparent conductive oxide such as indium tin oxide (ITO), indium zinc oxide (IZO), indium gallium oxide (IGO) or indium gallium zinc oxide (IGZO), but the embodiments of the present disclosure are not limited thereto. For example, the second electrode CE2 may be disposed in contact with the cathode electrode 135. For example, the second electrode CE2 may overlap the first optical layer 117a. For example, the second electrode CE2 may cover a flat outer surface of the first optical layer 117a.

The second electrode CE2 may extend continuously in the first direction X of the substrate 110. Accordingly, the second electrode CE2 may be commonly connected to the plurality of pixels PX arranged in the first direction X of the substrate 110. For example, the second electrode CE2 may be commonly connected to the plurality of pixels PX.

According to the present disclosure, the second electrode CE2 may continuously extend on the first optical layer 117a, the third optical layer 117c, and the light emitting element ED. The area where the first optical layer 117a is disposed may include the concave portion that is sunk inward from the upper surface of the third optical layer 117c. Accordingly, since a first portion of the second electrode CE2 disposed on the first optical layer 117a may be disposed along the concave portion, the first portion may be disposed at a lower position than a second portion of the second electrode CE2 disposed on the third optical layer 117c.

The second optical layer 117b may be disposed on the second electrode CE2. The second optical layer 117b may be disposed to overlap the plurality of light emitting elements ED and the first optical layer 117a. Since the second optical layer 117b is disposed on the second electrode CE2 and the plurality of light emitting elements ED, it is possible to remove a mura that may be generated on some of the plurality of light emitting elements ED. For example, when the plurality of light emitting elements ED are transferred onto the substrate 110 of the display device 1000, an area where spacings between the plurality of light emitting elements ED are not uniform due to process deviation or the like may occur. When the spacings between the plurality of light emitting elements ED are not uniform, light emitting areas of the plurality of light emitting elements ED may be disposed nonuniformly and thus a mura may be visible to a user. Accordingly, since the second optical layer 117b is configured to uniformly diffuse light onto the plurality of light emitting elements ED, it is possible to reduce light emitted from some of the light emitting elements ED that is visible as a mura. Accordingly, since the light emitted from the plurality of light emitting elements ED is uniformly diffused by the second optical layer 117b and extracted to the outside of the display device 1000, the luminance uniformity of the display device 1000 can be improved.

The second optical layer 117b may be made of an organic insulating material in which fine particles are dispersed, but the embodiments of the present disclosure are not limited thereto. For example, the second optical layer 117b may be made of a siloxane in which fine metal particles such as titanium dioxide (TiO2) particles are dispersed, but the embodiments of the present disclosure are not limited thereto. For example, the second optical layer 117b may be made of the same or different materials as the first optical layer 117a, but the embodiments of the present disclosure are not limited thereto. For example, the second optical layer 117b may be a diffusion layer, an upper surface diffusion layer, or the like, but the embodiments of the present disclosure are not limited thereto.

According to the present disclosure, light from the plurality of light emitting elements ED may be scattered by fine particles dispersed in the second optical layer 117b and emitted to the outside of the display device 1000. The second optical layer 117b can evenly mix the light emitted from the plurality of light emitting elements ED, thereby further improving the luminance uniformity of the display device 1000. Further, the light extraction efficiency of the display device 1000 can be improved by the light scattered in the plurality of fine particles, thereby enabling the display device 1000 to be driven at low power.

A black matrix BM may be disposed on the second electrode CE2, the first optical layer 117a, the third optical layer 117c, and the second optical layer 117b in the display area AA. For example, the black matrix BM may fill a contact hole of the third optical layer 117c. Since the black matrix BM is configured to cover the display area AA, it is possible to reduce mixing of light and reflection of external light in the plurality of sub-pixels. For example, since the black matrix BM is also disposed in the contact hole where the second electrode CE2 and the contact electrode CCE are connected, it is possible to prevent or at least reduce light from leaking between the plurality of adjacent sub-pixels.

For example, the black matrix BM may be configured of an opaque material, but the embodiments of the present disclosure are not limited thereto. For example, the black matrix BM may be an organic insulating material to which a black pigment or a black dye is added such as carbon black, Kochen black, nigrosine, but the embodiments of the present disclosure are not limited thereto.

A cover layer 118 may be disposed on the black matrix BM in the display area AA. The cover layer 118 may protect a configuration below the cover layer 118. For example, the cover layer 118 may be made of an organic insulating material, but the embodiments of the present disclosure are not limited thereto. For example, the cover layer 118 may be made of an acrylic resin, a phenolic resin, an unsaturated polyester resin, a polyamide resin, a benzocyclobutene, a polyphenylene resin, a polyphenylene sulfide resin, a photo resist, a polyimide (PI), a photo acryl-based material, or the like, but the embodiments of the present disclosure are not limited thereto. For example, the cover layer 118 may be an overcoating layer, an insulating layer, or the like, but the embodiments of the present disclosure are not limited thereto.

The polarizing layer 293 may be disposed on the cover layer 118 via a first adhesive layer 291. The cover member 120 may be disposed on the polarizing layer 293 via a second adhesive layer 295. For example, the first adhesive layer 291 and the second adhesive layer 295 may include a silicone resin, an epoxy resin, a UV curable resin, a polyimide resin, an acryl resin, a urethane resin, and polydimethylsiloxane (PDMS), an optically clear adhesive (OCA), an optically clear resin (OCR), or a pressure sensitive adhesive (PSA), but the embodiments of the present disclosure are not limited thereto.

According to the present disclosure, the plurality of pad electrodes PE may be disposed on the third insulating layer 115c in the second non-display area NA2. For example, at least a portion of the plurality of pad electrodes PE may be exposed from the passivation layer 116. For example, the plurality of pad electrodes PE may be electrically connected to the (2-4)-th connection wiring 122d through a contact hole of the third insulating layer 115c, in turn electrically connected to the (2-3)-th connection lines 122c through contact holes in the second insulating layer 115c, in turn electrically connected to the (2-2)-th connection lines 122b through contact holes in the first insulating layer 115a and in turn electrically connected to the (2-1)-th connection lines 122a through contact holes in the third protection layer 114.

An adhesive layer ACF may be disposed on the plurality of pad electrodes PE. The adhesive layer ACF may be an adhesive layer in which conductive balls are dispersed in an insulating material, but the embodiments of the present disclosure are not limited thereto. When heat or pressure is applied to the adhesive layer ACF, the conductive balls may be electrically connected at a portion to which the heat or pressure is applied, and have conductive properties. The adhesive layer ACF is disposed between the plurality of pad electrodes PE and/or the flexible circuit board (or flexible film) CB to attach or bond the flexible circuit board (or flexible film) CB to the plurality of pad electrodes PE. For example, the adhesive layer ACF may be an anisotropic conductive film (ACF), but the embodiments of the present disclosure are not limited thereto.

The flexible circuit board (or flexible film) CB may be disposed on the adhesive layer ACF. The flexible circuit board (or flexible film) CB may be electrically connected to the plurality of pad electrodes PE through the adhesive layer ACF. Therefore, a signal output from the flexible circuit board (or flexible film) CB and the printed circuit board may be transmitted to the pixel driver PD in the display area AA through the plurality of pad electrodes PE, the (2-4)-th connection wiring 122d, the (2-3)-th connection wiring 122c, the (2-2)-th connection wiring 122b, and the (2-1)-th connection wiring 122a.

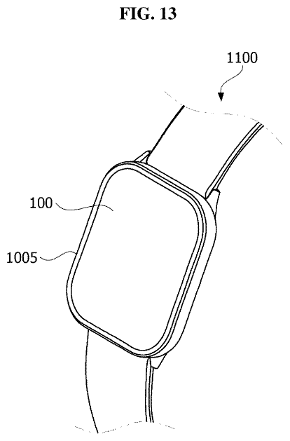

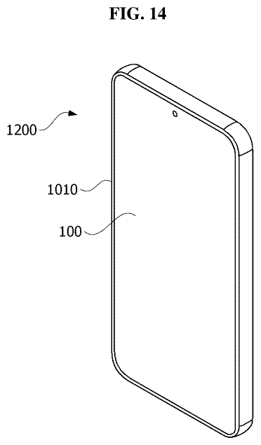

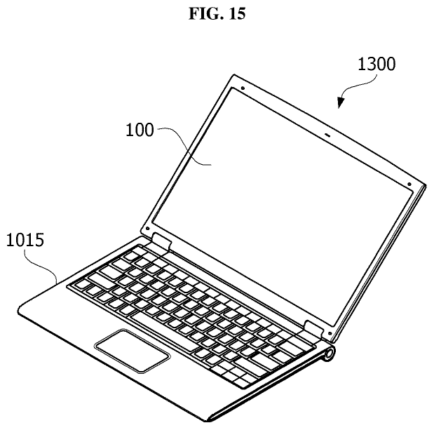

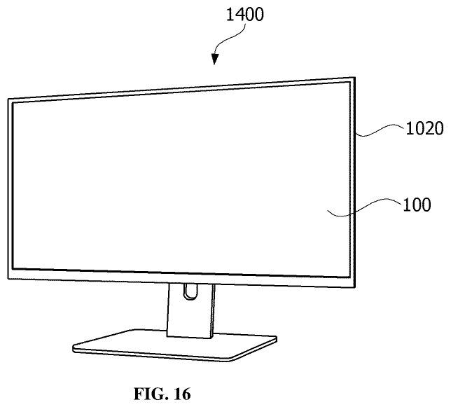

FIGS. 13 to 16 are diagrams illustrating devices to which the display device according to embodiments of the present disclosure is applied.

Referring to FIGS. 13 to 16, the display device 1000 according to the embodiments of the present disclosure may be included in various devices or electronic devices. For example, referring to FIGS. 13 to 16, various electronic devices may include a wearable device 1100, a mobile device 1200, a laptop computer 1300, and a monitor or TV 1400, but the embodiments of the present disclosure are not limited thereto.

The wearable device 1100, the mobile device 1200, the laptop computer 1300, and the monitor or TV 1400 may respectively include cases 1005, 1010, 1015, and 1020, and the display panel 100 and the display device 1000 according to the embodiments of the present disclosure described above.

For example, the display device according to the embodiment of the present disclosure may be applied to a mobile device, a video phone, a smart watch, a watch phone, a wearable apparatus, a foldable apparatus, a rollable apparatus, a bendable apparatus, a flexible apparatus, a curved apparatus, a sliding apparatus, a variable apparatus, an electronic notebook, an electronic book, a portable multimedia player (PMP), a personal digital assistant (PDA), an MP3 player, a mobile medical device, a desktop PC, a laptop PC, a netbook computer, a workstation, a navigation device, a vehicle display device, a theater display device, a television, a wallpaper device, a signage device, a game device, a laptop computer, a monitor, a camera, a camcorder, a home appliance, and the like.

The in-cell touch display panel according to one or more embodiments of the present disclosure may be described as follows.

The in-cell touch display panel according to one or more embodiments of the present disclosure may include a first common electrode connected to N*M (N and M are positive integers greater than or equal to 2) first pixels disposed in a display area, a second common electrode connected to N*M second pixels disposed in the display area, and a first pixel driver disposed in the display area to write pixel data to the first pixels and the second pixels and supply a voltage to the first common electrode and the second common electrode.

In the in-cell touch display panel according to one or more embodiments of the present disclosure, the first pixel driver may be electrically connected to the first pixels and the second pixels through a plurality of connection wirings, and may be electrically connected to the first common electrode and the second common electrode through a plurality of connection wirings.

In the in-cell touch display panel according to one or more embodiments of the present disclosure, the connection wirings may be disposed at different heights in a Z-axis direction of a height direction of the display panel between a plurality of insulating layers, and the connection wirings may be electrically connected to each other through contact holes disposed in the insulating layers.

In the in-cell touch display panel according to one or more embodiments of the present disclosure, the first pixel driver may be disposed in an overlapping manner between the first common electrode and the second common electrode.

In the in-cell touch display panel according to one or more embodiments of the present disclosure, the first pixel driver may be disposed to overlap some of the first pixels and the second pixels.

In the in-cell touch display panel according to one or more embodiments of the present disclosure, the connection wirings, the first common electrode, and the second common electrode may be electrically connected through a contact electrode.

In the in-cell touch display panel according to one or more embodiments of the present disclosure, the first common electrode and the second common electrode may include a first touch block and a second touch block, respectively.

The in-cell touch display panel according to one or more embodiments of the present disclosure, may further include a third common electrode connected to N*M third pixels disposed in the display area, a fourth common electrode connected to N*M fourth pixels disposed in the display area, and a second pixel driver that writes pixel data to the third pixels and the fourth pixels and supplies a voltage to the third common electrode and the fourth common electrode, wherein the second pixel driver may be disposed adjacent to the first pixel driver.

In the in-cell touch display panel according to one or more embodiments of the present disclosure, the pixels may include a plurality of sub-pixels, and each sub-pixel may include a first light emitting element that emits light in a first wavelength band, a second light emitting element that emits light in a second wavelength band, and a third light emitting element that emits light in a third wavelength band.

In the in-cell touch display panel according to one or more embodiments of the present disclosure, the first light emitting element may include an anode electrode, a first semiconductor layer disposed on the anode electrode, an active layer disposed on the first semiconductor layer, a second semiconductor layer disposed on the active layer, and a cathode electrode disposed on the second semiconductor layer.

In the in-cell touch display panel according to one or more embodiments of the present disclosure, the first light emitting element may have a vertical structure.

In the in-cell touch display panel according to one or more embodiments of the present disclosure, the first light emitting element may further include a solder pattern disposed below the anode electrode, and the anode electrode may be electrically connected through eutectic bonding by the solder pattern.

In the in-cell touch display panel according to one or more embodiments of the present disclosure, the first light emitting element may be a micro light emitting diode.

In the in-cell touch display panel according to one or more embodiments of the present disclosure, the first light emitting element, the second light emitting element, and the third light emitting element may be disposed in substantially the same structure.

In the in-cell touch display panel according to one or more embodiments of the present disclosure, the first light emitting element, the second light emitting element, and the third light emitting element may include, in one pixel, a main light emitting element and a redundant light emitting element that emits light with the same wavelength as the main light emitting element.

In the in-cell touch display panel according to one or more embodiments of the present disclosure, the main light emitting element and the redundant light emitting element may be disposed on the same bank.

In the in-cell touch display panel according to one or more embodiments of the present disclosure, the pixel driver may include a micro driver.

A driving method for an in-cell touch display panel according to one or more embodiments of the present disclosure may include sensing a touch input based on voltages received from the common electrodes.

According to the present disclosure, it is possible to reduce a thickness of the panel by using the common electrode as a touch electrode required for touch sensing of the in-cell touch display panel.

According to the present disclosure, it is possible to increase sensing accuracy and reduce time required for sensing by subdividing a touch group and a sensing period in the touch sensing of the in-cell touch display panel.

The effects of the present disclosure are not limited to the effects mentioned above, and other effects that are not mentioned can be clearly understood by those skilled in the art to which the technical spirit of the present disclosure belongs from the description below.

Although the embodiments of the present disclosure have been described in more detail with reference to the accompanying drawings, the present disclosure is not limited thereto and may be embodied in many different forms without departing from the technical concept of the present disclosure.

Therefore, the embodiments disclosed in the present disclosure are provided for illustrative purposes only and are not intended to limit the technical concept of the present disclosure.

The scope of the technical concept of the present disclosure is not limited thereto.

Therefore, it should be understood that the above-described embodiments are illustrative in all aspects and do not limit the present disclosure.

### DESCRIPTION OF REFERENCE SIGNS

100: Display panel
1005, 1010, 1015, 1020: Case
110: Substrate
112: Adhesive layer
114: Third protective layer
116: Passivation layer
118: Cover layer
120: Cover member
121: Plurality of first connection wirings
122: Plurality of second connection wirings
130: First light emitting element
130, 140, 150: Light emitting element
131: First semiconductor layer
132: Active layer
133: Second semiconductor layer
134: Anode electrode
135: Cathode electrode
136: Sealing film
140: Second light emitting element
150: Third light emitting element
160: Printed circuit board
180: Hole
291: First adhesive layer
293: Polarizing layer
295: Adhesive layer
AA: Display area
ACF: Adhesive layer
Ag: Silver
Al: Aluminum
Au: Gold
BA: Bending area
BM: Black matrix
BNK: Bank
Ba: Barium
Be: Beryllium
CB: Flexible circuit board
CCE: Contact electrode
CE1: First electrode
CE2: Second electrode
Ca: Calcium
Cr: Chromium
Cu: Copper
D1, D2, D3, D4: Display period
ED: Light emitting element
EM: Light emitting signal
PD: Pixel driver
SDP: Solder pattern
SP: Plurality of sub-pixels
SP1: First sub-pixel
SP2: Second sub-pixel
SP3: Third sub-pixel
T1, T2, T3, T4: Touch sensing period
T_{DR}: Driving transistor
T_{EM}: Light emitting transistor
TG: Touch group
TL: Signal wiring
TL1: First signal wiring
TL2: Second signal wiring
TL3: Third signal wiring
TL4: Fourth signal wiring
TL5: Fifth signal wiring
TL6: Sixth signal wiring
Te: Tellurium
Ti: Titanium
VDD: High potential power supply voltage
VL: Drive wiring
W: Tungsten
X: First direction
Y: Second direction
Zn: Zinc

What is claimed is:

1. A display panel comprising:
a first common electrode connected to first pixels in a display area;
a second common electrode connected to second pixels in the display area; and
a first pixel driver in the display area, the first pixel driver configured to supply pixel data to the first pixels and the second pixels and supply a voltage or a signal to the first common electrode and the second common electrode.

2. The display panel of claim 1, wherein the display panel includes an in-cell touch display panel.

3. The display panel of claim 1, further comprising:
a plurality of connection wirings that electrically connect the first pixel driver to the first pixels and the second pixels and electrically connect the first pixel driver to the first common electrode and the second common electrode.

4. The display panel of claim 3, wherein the plurality of connection wirings are located at different heights in the display panel and are between a plurality of insulating layers, and the plurality of connection wirings are electrically connected to each other through a plurality of contact holes in the plurality of insulating layers.

5. The display panel of claim 1, wherein the first pixel driver overlaps the first common electrode and the second common electrode.

6. The display panel of claim 1, wherein the first pixel driver overlaps a portion of the first pixels and a portion of the second pixels.

7. The display panel of claim 3, further comprising:
a plurality of contact electrodes that electrically connect each of the first common electrode and the second common electrode to the plurality of connection wirings.

8. The display panel of claim 1, wherein the first common electrode includes a first touch block to sense touch and the second common electrode includes a second touch block to sense touch.

9. The display panel of claim 1, further comprising:
a third common electrode connected to third pixels in the display area;
a fourth common electrode connected to fourth pixels in the display area; and
a second pixel driver adjacent to the first pixel driver in the display area, the second pixel driver configured to supply pixel data to the third pixels and the fourth pixels and supply a voltage or a signal to the third common electrode and the fourth common electrode.

10. The display panel of claim 1, wherein each of the first pixels and the second pixels includes a plurality of sub-pixels that comprise:
a first light emitting element configured to emit light in a first wavelength band;
a second light emitting element configured to emit light in a second wavelength band; and
a third light emitting element configured to emit light in a third wavelength band.

11. The display panel of claim 10, further comprising a first optical layer surrounding the first light emitting element, the first optical layer comprising an organic insulating material in which fine particles are dispersed.

12. The display panel of claim 10, wherein the first light emitting element includes:
an anode electrode;
a first semiconductor layer on the anode electrode;
an active layer on the first semiconductor layer;
a second semiconductor layer on the active layer; and
a cathode electrode on the second semiconductor layer.

13. The display panel of claim 12, further comprising a sealing film disposed on at least a portion of the first semiconductor layer, the second semiconductor layer, the anode electrode and the cathode electrode, the sealing film comprising a reflective material dispersed in a resin layer.

14. The display panel of claim 12, wherein the first light emitting element has a vertical structure.

15. The display panel of claim 12, wherein the first light emitting element further comprises:
a solder pattern on the anode electrode such that the anode electrode is between the solder pattern and the first semiconductor layer, and
wherein the anode electrode is electrically connected to the solder pattern.

16. The display panel of claim 12, wherein the first light emitting element includes a micro light emitting diode.

17. The display panel of claim 12, wherein the first light emitting element, the second light emitting element, and the third light emitting element have a same structure.

18. The display panel of claim 10, wherein the first light emitting element, the second light emitting element, and the third light emitting element each include a main light emitting element and a redundant light emitting element configured to emit light with a same wavelength as the main light emitting element.

19. The display panel of claim 18, further comprising:
a plurality of banks,
wherein for each of the first light emitting element, the second light emitting element, and the third light emitting element, both the main light emitting element and the redundant light emitting element of the light emitting element are on the bank for the light emitting element.

20. The display panel of claim 1, wherein the first pixel driver includes a micro driver.

21. The display panel of claim 1, further comprising:
a first contact electrode connected to the first common electrode;
a second contact electrode connected to the second common electrode; and
a communication wiring between the first contact electrode and the second contact electrode.

22. The display panel of claim 12, further comprising:
a passivation layer on the anode electrode; and
a conductive layer included in the anode electrode, the conductive layer including a surface that is in contact with the passivation layer.

23. A display device comprising:
a plurality of pixels in a display area that displays an image;
a plurality of touch units that each include a plurality of touch groups, wherein each of the plurality of touch groups of each of the plurality of touch units comprises a first touch group including a first common electrode that is connected to first pixels of the touch unit from the plurality of pixels and a second touch group including a second common electrode that is connected to second pixels of the touch unit from the plurality of pixels but not the first pixels of the touch unit; and
a pixel driver configured to output a touch driving signal to the first common electrode of the first touch group of each of the plurality of touch units to sense touch of the first touch group during a first touch period and output a common voltage to the second common electrode of the second touch group of each of the plurality of touch units during the first touch period such that the second pixels of each of the plurality of touch units display an image during the first touch period.

24. The display device of claim 23, wherein the pixel driver is further configured to output the touch driving signal to the second common electrode of the second touch group of each of the plurality of touch units to sense touch of the second touch group during a second touch period and output the common voltage to the first common electrode of the first touch group of each of the plurality of touch units during the second touch period such that the first pixels of each of the plurality of touch units displays the image during the second touch period,
wherein the first touch period and the second touch period are included in one frame.

25. The display device of claim 24, wherein the pixel driver is further configured to output the common voltage to the first common electrode of the first touch group of each of the plurality of touch units and to the second common electrode of the second touch group of each of the plurality of touch units during a display period such that the first pixels of each of the plurality of touch units and the second pixels of each of the plurality of touch units display the image during the display period,
wherein the display period is included in the one frame.

26. The display device of claim 25, wherein the pixel driver is in the display area and is further configured to supply pixel data corresponding to the image to the second pixels during the first touch period, supply the pixel data corresponding to the image to the first pixels during the second touch period, and is configured to supply the pixel data corresponding to the image to the first pixels and the second pixels during the display period.

27. The display device of claim 23, further comprising:
a plurality of connection wirings that electrically connect the pixel driver to the first pixels and the second pixels and electrically connect the pixel driver to the first common electrode and the second common electrode.

28. The display device of claim 23, wherein the pixel driver overlaps the first common electrode and the second common electrode.

29. The display device of claim 23, wherein the pixel driver overlaps a portion of the first pixels and a portion of the second pixels.
